(19) United States
(12) Patent Application Publication
(10) Pub. No.: US 2004/0013271 A1
(43) Pub. Date: Jan. 22, 2004

(54) Method and system for recording and reproduction of binaural sound

(76) Inventor: Surya Moorthy, Victoria (AU)

Correspondence Address: LARSON & TAYLOR, PLC, 1199 NORTH FAIRFAX STREET, SUITE 900, ALEXANDRIA, VA, 22314, US

(21) Appl. No.: 10/344,516

(22) PCT Filed: Aug. 14, 2001
(86) PCT No.: PCT/AU01/00998

(30) Foreign Application Priority Data
Aug. 14, 2000 (AU) PQ 9380

(51) Int. Cl. H04R 5/00; H03G 5/00

(52) U.S. Cl. 381/1; 381/98; 381/17

(57) ABSTRACT

The invention provides an apparatus for the reproduction of sound in a listening environment, the sound including a left channel and a right channel and each of the channels including a high frequency component and a low frequency component. The apparatus comprises: means for comparing the left and right channels and forming left and right comparison signals therefrom; at least one left loudspeaker means for reproducing the left channel and the left comparison signal; and at least one right loudspeaker means for reproducing the right channel and the right comparison signal; wherein the apparatus is operable to reproduce the first and second comparison signals by means of the loudspeaker means, and the left and right comparison signals are, or the apparatus is operable to reproduce the left and right comparison signals to be, substantially incoherent with respect to each other and at a low level relative to the left and right channels, to produce a binaural effect for a listener in the listening environment.

### FIELD OF THE INVENTION

The present invention relates to the recording and reproduction of binaural sound, of particular but by no means exclusive application in the recording of musical performances and the reproduction of those recordings or of existing stereophonic recordings. Binaural sound refers to natural hearing conditions, whereby a single source of sound emits only one sound signal to each of a listener's two ears.

### BACKGROUND OF THE INVENTION

Although the invention is described here mainly in terms of domestic, small room listening environments, the invention is also applicable to a variety of other non-domestic settings including, for example, sound reproduction systems for automobiles, sound reproduction systems for professional concert venues and public address systems, calibration of concert halls, acoustic design of buildings, acoustic simulators, personal computer sound systems, virtual reality sound systems and professional recording systems and reproduction systems for music-sound studios and film-sound studios.

Existing systems for the stereophonic recording of sound, in their simplest form, employ a pair of coincident microphones centrally located forward of, for example, a musical or other live performance. Various modifications of this arrangement are often employed to compensate for stereophonic inadequacies, which are generally due to limitations in the reproduction of the recorded sound. For example, in order to reproduce faithfully the geometry of the recording session with these existing systems, a listener must be located within a very narrow ‘sweet spot’ relative to the distance between the (commonly) two front loudspeakers. Even so, the apparent positions of different sources of sound in the original performance (such as separate sections of an orchestra) may not be faithfully simulated during reproduction of the sound, owing to the different dominant frequencies of such separate sound sources and the differential manner in which the human ear responds to different frequencies. Further, the acoustics of the listening environment will generally differ from those of the original recording, and consequently be superimposed, with adverse consequences, on the reproduced sound.

Many of the flaws in the reproduced sound have been discussed in the audio technical literature since GB Patent No. 394,325 (Blumlein), which taught improvements in and relating to sound-transmission, stereophonic sound-recording and stereophonic sound-reproducing systems.

Many of the existing measures used to ameliorate the effects of these flaws are employed during recording, and others during signal processing or reproduction. During recording, for example, the two microphones may be separated by a dummy ‘head’ to simulate the sound ‘shadowing’ effect of a real listener's head, whereby sound from the right audio field is diffracted (or ‘shadowed’) and altered in spectral or frequency content before being received by the left ear, and vice versa for the right ear. When played back through stereophonic headphones, such recordings result in a realistic binaural effect for the listener in terms of three dimensional sound localization. In another example, two or more microphones will be used in a so-called “spaced array” configuration, with the microphones commonly separated by distances much greater than the typical separation of a listener's ears in an attempt to increase the perception of space conveyed to the listener upon the stereophonic reproduction of the recording.

The two stereophonic channels may each be reproduced through a plurality of loudspeakers distributed around the listening environment, while some existing ‘home theatre’ systems include an additional ‘centre channel’ loudspeaker located on an axis between the two primary front loudspeakers to anchor central sounds for off-centre listeners. The signal for this centre channel is usually a form of monophonic signal derived from the sum of the left and right signals. A number of examples of the use of particular sum and difference signals in various specific ways to ameliorate some of the flaws of standard left and right stereophonic sound reproduction are well known. GB Patent No. 781,186 (Vanderlyn) teaches the substitution, for the conventional left and right channels, of channels derived respectively from the sum of the left and right channels, and the difference between the left and right channels.

It is an object of the present invention to provide a method and apparatus for reproducing recorded sound whereby a listener has an improved experience of the spaciousness of the original recording venue and a reduced impression of the superimposed spaciousness of the listening environment.

### SUMMARY OF THE INVENTION

Accordingly, the present invention provides an apparatus for the reproduction of sound in a listening environment, said sound including a left channel and a right channel and each of said channels including a high frequency component and a low frequency component, including:

means for comparing said left and right channels and forming left and right comparison signals therefrom;

at least one left loudspeaker means for reproducing said left channel and said left comparison signal; and

at least one right loudspeaker means for reproducing said right channel and said right comparison signal;

wherein said apparatus is operable to reproduce said first and second comparison signals by means of said loudspeaker means, and said left and right comparison signals are, or said apparatus is operable to reproduce said left and right comparison signals to be, substantially incoherent with respect to each other and at a low level relative to said left and right channels, to produce a binaural effect for a listener in said listening environment.

Low level in this context means lower than the left and right channels and, indeed, preferably lower than comparable signals in the prior art. For example, where the comparison signals are subwoofer bass signals, the signals will preferably be reproduced at lower levels than such signals are usually reproduced in prior art stereophonic systems.

Preferably said means for comparing said left and right channels and forming left and right comparison signals therefrom is operable to form a plurality of pairs of left and right comparison signals therefrom.

Preferably each of said low frequency components comprises frequencies below approximately 700 Hz and each of said high frequency components comprises frequencies above approximately 700 Hz.

Preferably said means for forming a comparison between said left and right channels and forming left and right comparison signals therefrom comprises:

means for deriving said left comparison signal in the form of a left ambience signal comprising a low frequency difference signal derived from said left low frequency component minus said right low frequency component; and

means for deriving said right comparison signal in the form of a right ambience signal comprising a low frequency difference signal derived from said right low frequency component minus said left low frequency component;

wherein said apparatus is operable to reproduce said left and right ambience signals substantially temporally coherently relative to said left and right channels, whereby a listener's awareness of unwanted primary sound reflections in said listening environment is reduced or eliminated.

Preferably said apparatus is operable to reproduce said left and right ambience signals with substantially zero imposed time delay relative to said left and right channels.

Preferably said low level is as low as possible while providing ambient sound.

Preferably said low level is such that said left ambience signal is approximately −20 dB relative to said left channel and said right ambience signal is approximately −20 dB relative to said right channel.

Preferably said means for deriving said left and right ambience signals are operable to process said left and right ambience signals by means of the “shuffler” circuit described in GB Patent No. 781,186 or an equivalent thereof.

Preferably said means for deriving said left and right ambience signals are operable to augment said left and right ambience signals with a narrow bandwidth signal centred at approximately 500 Hz, to increase the extent to which a listener will perceive the resultant augmented left and right ambience signals as coming from a lateral direction.

Preferably said narrow bandwidth signal is a ‘spike’, signal with a width of approximately ⅓ octave. Preferably said means for deriving said left and right ambience signals are operable to adjust said signal in width and/or amplitude.

Preferably said left and right loudspeaker means are calibrated to produce a flat overall power response from 15 Hz to 20 kHz determined with a calibration microphone located in the median plane with respect to said loudspeaker means, and at a normal near-field listening distance therefrom, so that left and right primary front loudspeaker means subtend an angle of substantially 90° at said calibration microphone.

Preferably each of said left and right loudspeaker means includes a main audio driver means for each of said respective left and right channels, and at least one ambience driver means for each of said respective left and right ambience signals.

Preferably said main audio driver means of each of said loudspeaker means includes one or more mid-range to high frequency audio drivers for reproducing mid-range to high frequency components of said respective left and right channels, wherein said one or more mid-range to high frequency audio drivers are highly directional, that is, have a low sound dispersion.

Preferably said mid-range to high frequency audio drivers of each of said loudspeaker means are arranged to act collectively as a line source of sound energy with respect to a listener.

Preferably each of said loudspeaker means includes a wide baffle, wherein said respective mid-range to high frequency audio drivers are arranged on said respective wide baffles, wherein said wide baffles are optimally, in use, located opposite and facing each other.

Preferably said at least one ambience driver of said left loudspeaker means is located on said left loudspeaker means to direct reproduced sound in a direction substantially perpendicular to that of reproduced sound from said mid-range to high frequency audio drivers of said left loudspeaker means, and said at least one ambience driver of said right loudspeaker means is located on said right loudspeaker means to direct reproduced sound in a direction substantially perpendicular to that of reproduced sound from said mid-range to high frequency audio drivers of said right loudspeaker means.

Preferably said apparatus further includes a left ambience loudspeaker means for locating laterally left of a listener and a right ambience loudspeaker means for locating laterally right of said listener, whereby said left ambience loudspeaker means is for reproducing said left ambience signal and said right ambience loudspeaker means is for reproducing said right ambience signal.

Preferably said means for comparing said left and right channels includes:

means for deriving a left high frequency difference signal from said high frequency components; and

means for deriving a right high frequency difference signal from said high frequency components;

wherein said apparatus is configured to reproduce said left and right high frequency difference signals substantially coherently relative to said left and right channels and to set or to adjust the amplitudes of said left and right high frequency difference signals relative to said left and right channels and left and right ambience signals to maximize the binaural effect for a listener in said listening environment.

Preferably said apparatus is operable to reproduce said left and right high frequency difference signals with substantially zero imposed time delay relative to said left and right channels.

Preferably said left high frequency difference signal is derived from said right high frequency component minus said left high frequency component; and

said right high frequency difference signal is derived from said left high frequency component minus said right high frequency component.

Preferably said left loudspeaker means includes one or more left tweeter drivers to act collectively as a line source for reproducing said left high frequency difference signal, and said right loudspeaker means includes one or more right tweeter drivers to act collectively as a line source for reproducing said right high frequency difference signal, wherein said left tweeter drivers are located on said left loudspeaker means to direct reproduced sound in a direction substantially opposite to that of reproduced sound from said mid-range and higher frequency audio drivers of said left loudspeaker means, and said right tweeter drivers are located on said right loudspeaker means to direct reproduced sound in a direction substantially opposite to that of reproduced sound from said mid-range and higher frequency audio drivers of said right loudspeaker means.

Preferably each of said left and right loudspeaker means includes an external tweeter baffle on which are located said respective left and right tweeter drivers.

Preferably said apparatus includes means for deriving left and right reverberation signals from the difference between said left channel and said right channel, wherein said left and right reverberation signals are substantially temporally incoherent with respect to said left and right channels, are substantially incoherent with respect to each other and are, or said apparatus is operable for reproducing said left and right reverberation signals, at a low level relative to said left and right channels so as to provide reverberant sound.

Preferably the means for deriving left and right reverberation signals is operable to derive said left reverberation signal from said left channel minus said right channel, and said right reverberation signal from said right channel minus said left channel.

Preferably said low level is such that said left reverberation signal is approximately −16 dB relative to said left channel and said right reverberation signal is approximately −16 dB relative to said right channel.

Preferably said left and right reverberation signals are delayed relative to said respective left and right channels, more preferably by approximately 20 to 40 ms.

Still more preferably, a first of said left and right reverberation signals is delayed relative to said respective left or right channel by approximately 20 ms, and the other of said left and right reverberation signals is delayed relative to the first by a further 20 ms.

Preferably said means for deriving said first and second reverberation signals are operable to said first and second reverberation signals by means of the “shuffler” circuit described in GB Patent No. 781,186 or equivalent.

Preferably said means for deriving said first and second reverberation signals are operable to modify said first and second reverberation signals to simulate the shadowing effect on said first and second reverberation signals of the head of a listener by means of a head related transfer function that simulates said shadowing. More preferably, said means for deriving said first and second reverberation signals are operable to modify said first and second reverberation signals by respective first and second different differential head related transfer functions. Preferably each of said differential head related transfer functions is in the form of an approximation including a plurality of narrow bandwidth peaks and troughs of different amplitudes, wherein said peaks and troughs differ between differential head related transfer functions.

Thus, as the differential head related transfer functions include both peaks and troughs, the reverberation signals may be both augmented and filtered.

Preferably said apparatus includes a left reverberation loudspeaker means for locating laterally left of a listener and a right reverberation loudspeaker means for locating laterally right of said listener, whereby said left reverberation loudspeaker means is for reproducing said left reverberation signal and said right reverberation loudspeaker means is for reproducing said right reverberation signal.

Preferably, when said apparatus includes left and right ambience loudspeaker means, said left ambience loudspeaker means is said left reverberation loudspeaker means, and said right ambience loudspeaker means is said right reverberation loudspeaker means.

Thus, a single pair of loudspeaker means can include driver means for reproducing both the ambience and reverberation signals. The ambience signals may be reproduced by means of standard cone drivers, and the reverberation signals by means of a pair of standard cone drivers in a dipole configuration.

Preferably said means for comparing said left and right channels includes:

means for deriving a left subwoofer signal from a first combination of signals comprising:

a very low frequency component of said left channel,

a difference component comprising said very low frequency component of said left channel minus a very low frequency component of said right channel, and

a summed component comprising said very low frequency component of said left channel plus said very low frequency component of right channel; and

means for deriving a right subwoofer signal from a second combination of signals comprising:

said very low frequency component of said right channel,

a difference component comprising said very low frequency component of said right channel minus said very low frequency component of said left channel, and

a summed component comprising said very low frequency component of said right channel plus said very low frequency component of said left channel,

wherein each of said first and second combinations are delayed relative to said respective left and right channels by between 15 and 1000 ms, and more preferably by between 20 and 300 ms.

This delay is preferably adjustable, and more preferably different for each of said first and second combinations.

Preferably said low level is such that said left subwoofer signal is approximately −25 dB relative to said left channel and said right subwoofer signal is approximately −25 dB relative to said right channel.

Preferably said apparatus includes combination adjustment means for adjusting said first and second combinations, so that said left and right subwoofer signals are substantially incoherent with respect to each other.

More preferably said subwoofer signals include lower and higher frequency components and said lower frequency components are amplified relative to said higher frequency components. Preferably the effective cross-over frequency of said difference components is different from that of said summed components, and said respective difference components include an imposed adjustable time delay relative to said respective summed components.

Still more preferably the apparatus is operable to modify the relative amplitudes of the components constituting said first and second combinations so that said difference components are received binaurally by each respective ear of a listener.

Preferably said left and right subwoofer signals have a maximum frequency cutoff of 50 Hz. Preferably said apparatus includes cutoff adjustment means for adjusting said cutoff.

The present invention also provides a method of reproducing a sound recording in a listening environment, said sound recording including a left channel and a right channel and each of said channels including a high frequency component and a low frequency component, including:

comparing said left and right channels and forming left and right comparison signals therefrom;

reproducing said left channel and said left comparison signal by means of at least one left loudspeaker means; and

reproducing said right channel and said right comparison signal by means of at least one right loudspeaker means;

whereby said left and right comparison signals are, or are reproduced as, substantially incoherent relative to each other and at a low level relative to said left and right channels, to produce a binaural effect for a listener in said listening environment.

Preferably said method includes comparing said left and right channels and forming a plurality of pairs of left and right comparison signals therefrom.

Preferably each of said low frequency components comprises frequencies below approximately 700 Hz and each of said high frequency components comprises frequencies above approximately 700 Hz.

Preferably said forming said left and right comparison signals includes:

deriving said left comparison signal in the form of a left ambience signal comprising a low frequency difference signal derived from said left low frequency component minus said right low frequency component; and

deriving said right comparison signal in the form of a right ambience signal comprising a low frequency difference signal derived from said right low frequency component minus said left low frequency component;

wherein said left and right ambience signals are reproduced substantially temporally coherently with said left and right channels, whereby a listener's awareness of unwanted primary sound reflections in said listening environment is reduced or eliminated.

Preferably said left and right ambience signals have, or are reproduced with, substantially zero imposed time delay with respect to said left and right channels.

Preferably said low level is as low as possible while providing ambient sound.

Preferably said low level is such that said left ambience signal is approximately −20 dB relative to said left channel and said right ambience signal is approximately −20 dB relative to said right channel.

Preferably said method includes processing said left and right ambience signals by means of the “shuffler” circuit described in GB Patent No. 781,186 or an equivalent thereof.

Preferably said method includes augmenting said left and right ambience signals with a narrow bandwidth signal centred at approximately 500 Hz, to increase the extent to which a listener will perceive the resultant augmented left and right ambience signals as coming from a lateral direction.

Preferably said narrow bandwidth signal is a ‘spike’ signal with a width of approximately ⅓ octave. Preferably said method includes adjusting said signal in width and/or amplitude to optimize said binaural effect.

Preferably said method includes calibrating said left and right loudspeaker means to produce a flat overall power response from 15 Hz to 20 kHz determined with a calibration microphone located in the median plane with respect to said loudspeaker means, and at a normal near-field listening distance therefrom, so that left and right primary front loudspeaker means subtend an angle of substantially 90° at said calibration microphone.

Preferably said method includes reproducing mid-range to high frequency components of said left and right channels highly directionally, that is, with low sound dispersion, and more preferably by means of respective main audio driver means comprising respective one or more highly directional mid-range to high frequency audio drivers.

Preferably said method includes arranging said mid-range to high frequency audio drivers of each of said loudspeaker means to act collectively as respective line sources of sound energy with respect to a listener.

Preferably said method includes arranging each of said respective mid-range to high frequency audio drivers on respective wide baffles on each of said respective loudspeaker means, and locating said wide baffles opposite and facing each other.

Preferably said method includes reproducing said left ambience signals in a direction substantially perpendicular to that of reproduced sound from said mid-range to high frequency audio drivers of said left loudspeaker means, and said right ambience signal in a direction substantially perpendicular to that of reproduced sound from said mid-range to high frequency audio drivers of said right loudspeaker means.

Preferably said method further includes reproducing said left ambience signal means laterally left of and generally towards a listener, and said right ambience signal laterally right of and generally towards said listener.

Preferably said forming said left and right comparison signals includes:

deriving a left high frequency difference signal from said high frequency components; and

deriving a right high frequency difference signal from said high frequency components;

reproducing said left and right high frequency difference signals substantially coherently relative to said left and right channels, and setting or adjusting the amplitudes of said left and right high frequency difference signals relative to said left and right channels and left and right ambience signals to maximize the binaural effect for a listener in said listening environment.

Preferably said method includes reproducing said left and right high frequency difference signals with substantially zero imposed time delay relative to said left and right channels.

Preferably said method includes deriving said left high frequency difference signal from said right high frequency component minus said left high frequency component; and

said method includes deriving said right high frequency difference signal from said left high frequency component minus said right high frequency component.

Preferably said method includes reproducing said left high frequency difference signal by means of one or more left tweeter drivers arranged to act collectively as a line source, and reproducing said right high frequency difference signal by means of one or more right tweeter drivers arranged to act collectively as a line source.

Preferably said method includes reproducing said left high frequency difference signal in a direction substantially opposite to that of said left channel, and reproducing said right high frequency difference signal in a direction substantially opposite to that of said right channel.

Preferably said method includes deriving left and right reverberation signals from the difference between said left and right channels, wherein said left and right reverberation signals are, or are reproduced, substantially temporally incoherent with respect to said left and right channels, substantially incoherent with respect to each other and at a low level relative to said left and right channels so as to provide reverberant sound.

Preferably said method includes deriving said left reverberation signal from said left channel minus said right channel, and said right reverberation signal from said right channel minus said left channel. Preferably said low level is such that said left reverberation signal is approximately −16 dB relative to said left channel and said right reverberation signal is approximately −16 dB relative to said right channel.

Preferably said method includes delaying said left and right reverberation signals relative to said respective left and right channels, more preferably by approximately 20 to 40 ms.

Still more preferably, a first of said left and right reverberation signals is delayed relative to said respective left or right channel by approximately 20 ms, and the other of said left and right reverberation signals is delayed relative to the first by a further 20 ms.

Preferably said method includes processing said first and second reverberation signals by means of the “shuffler” circuit described in GB Patent No. 781,186 or equivalent.

Preferably said method includes modifying said first and second reverberation signals to simulate the shadowing effect on said first and second reverberation signals of the head of a listener by means of a head related transfer function that simulates said shadowing. More preferably, said method includes modifying said first and second reverberation signals by means of respective first and second different differential head related transfer functions. Preferably each of said differential head related transfer functions is in the form of an approximation including a plurality of narrow bandwidth peaks and troughs of different amplitudes, wherein said peaks and troughs differ between differential head related transfer functions.

Preferably said method includes reproducing said left and right reverberation signals from left and right of, and generally towards, a listener, respectively.

Preferably said forming said left and right comparison signals includes:

deriving a left subwoofer signal from a first combination of signals comprising:

a very low frequency component of said left channel,

a difference component comprising said very low frequency component of said left channel minus a very low frequency component of said right channel, and

a summed component comprising said very low frequency component of said left channel plus said very low frequency component of right channel; and

deriving a right subwoofer signal from a second combination of signals comprising:

said very low frequency component of said right channel,

a difference component comprising said very low frequency component of said right channel minus said very low frequency component of said left channel, and

a summed component comprising said very low frequency component of said right channel plus said very low frequency component of said left channel;

wherein each of said first and second combinations are delayed relative to said respective left and right channels by between 15 and 1000 ms, and more preferably by between 20 and 300 ms.

Preferably said low level is such that said left subwoofer signal is approximately −25 dB relative to said left channel and said right subwoofer signal is approximately −25 dB relative to said right channel.

Preferably said method includes adjusting said first and second combinations, so that said left and right subwoofer signals are substantially incoherent with respect to each other. More preferably said subwoofer signals include lower and higher frequency components, and said method includes amplifying said lower frequency components relative to said higher frequency components. Preferably the effective cross-over frequency of said difference components is different from that of said summed components, and said method includes imposing an adjustable time delay on said respective difference components relative to said respective summed components.

Still more preferably said method includes modifying the relative amplitudes of said components so that said difference components are received binaurally by each respective ear of a listener.

Preferably said left and right subwoofer signals have a maximum frequency cutoff of approximately 50 Hz.

Preferably said method includes adjusting said cutoff.

The present invention also provides a method for remastering existing stereophonic sound recordings, comprising deriving ambience, reverberation and/or subwoofer signals as described above in the above method for reproducing sound, and re-recording each of or combinations of said left and right channels and the signals derived therefrom.

The present invention also provides a method of recording binaural sound, including extracting initial left and right channels from respective left and right microphones, processing said left and right channels to comparison signals (including, for example, ambience, reverberation and/or subwoofer signals as described above), and recording each of or combinations of said left and right channels and said signals derived therefrom.

Preferably said microphones for recording said initial left and right channels are coincident microphones.

### BRIEF DESCRIPTION OF THE DRAWINGS

In order that the present invention may be more clearly ascertained, preferred embodiments will now be described, by way of example, with reference to the accompanying drawing, in which:

FIG. 1 is a schematic representation of direct signals and primary room-reflected signals received by a listener located off-centre with respect to two front loudspeakers manufactured and positioned according to a standard stereo or home theatre configuration of the prior art;

FIG. 2 is a schematic representation of direct signals and primary room-reflected signals received by a listener located off-centre with respect to two front loudspeakers in accordance with a binaural sound reproduction system according to a preferred embodiment of the present invention;

FIG. 3 is a differential frequency spectrum for the inner ear head related transfer function (HRTF) corresponding to the shadowing effect of a listener's head;

FIG. 4 is a ‘spike’ approximation of the function of FIG. 3, used to augment reverberation signals of the system of FIG. 2;

FIG. 5 is a schematic representation of concert hall listening conditions, showing the total early sound energy impinging on a listener divided into three components NL, L and R;

FIG. 6 depicts the relationship between the degree of spatial impression (or “spatial broadening”) of the sound image, SI, and the degree of incoherence 1−K⁰⁻⁸⁰;

FIG. 7 depicts the feasible range for the degree of incoherence 1−K⁰⁻⁸⁰ in the median plane of a concert hall;

FIG. 8 represents the presence of additional late sound energy components L′ and R′ due to the reverberant soundfield;

FIG. 9 is a schematic representation of traditional stereo listening conditions of the prior art, with the total early sound energy impinging on the listener divided into three components NL, L and R;

FIG. 10 is a schematic representation of contemporary home theatre listening conditions of the prior art, with the total early sound energy impinging on the listener divided into three components NL, L and R; and

FIG. 11 is a schematic representation of Binaural Spatial Surround listening conditions according to the present invention, with the total early sound energy impinging on the listener divided into three components NL, L and R.

### DETAILED DESCRIPTION

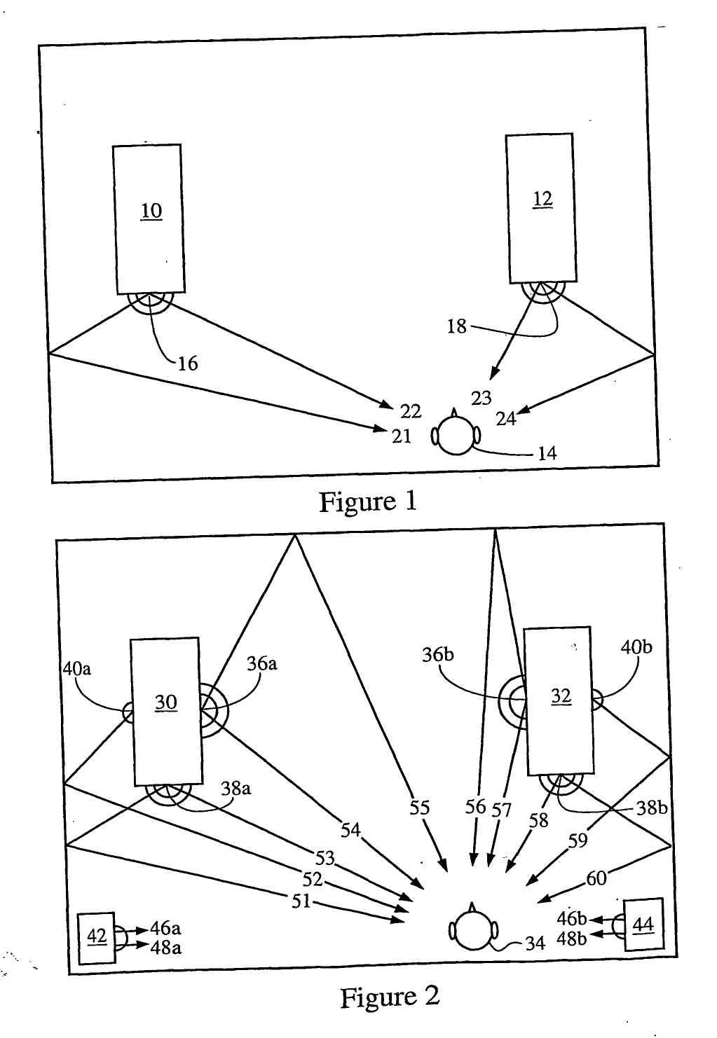

In order to ascertain the present invention, it will be useful to describe the analogous situation with traditional stereo or contemporary home theatre configurations (front stereo loudspeaker pair only). Such a system is depicted schematically in FIG. 1, and includes left loudspeaker 10 and right loudspeaker 12. A listener 14 is located off-centre. Each loudspeaker 10,12 includes a plurality of respective drivers 16,18 located on the forward face (i.e. generally towards listener 14) of loudspeakers 10,12.

Each ear perceives components from both speakers: these will be designated as follows (with reference to the signal numbering of FIG. 1):

| Low frequency signals | | High frequency signals | |
|---|---|---|---|
| reaching the left ear | | reaching the left ear | |
| 21 | −L_{direct, reflected} | 21 | −l_{direct, reflected} |
| 22 | L_{direct} | 22 | l_{direct} |
| 23 | R_{direct, diffracted} | 23 | r_{direct, diffracted} |
| 24 | −R_{direct, reflected, diffracted} | 24 | −r_{direct, reflected, diffracted} |

The listener's left ear perceives the sum of these signals:

$$\begin{matrix}{L}_{direct} - {L}_{direct , reflected} + {R}_{direct , diffracted} - \\ {R}_{direct , reflected , diffracted} + {l}_{direct} - {l}_{direct , reflected} + \\ {r}_{direct , diffracted} - {r}_{direct , reflected , diffracted}\end{matrix}$$

The last signal is negligible owing to the diffraction (head shielding) effect on this high frequency component of signal no. 24 in reaching the left ear. Thus, the listener's left ear effectively perceives:

$$\begin{matrix}( {L}_{full bandwidth , direct} - {L}_{full bandwidth , direct , reflected} ) + \\ Δ {R}_{direct , diffracted} + {r}_{direct , diffracted}\end{matrix}$$

where the prefix ‘Δ’ denotes the intensity loss of any signal as a result of a single wall reflection.

Using a similar analysis, the listener's right ear effectively perceives:

(R_{full bandwidth,direct}−R_{full bandwidth,direct,reflected})+ΔL_{direct,diffracted}+l_{direct,diffracted}

Thus, full high frequency interaural cross-talk is present.

A binaural sound reproduction system according to a preferred embodiment of the present invention is shown schematically in FIG. 2. This system includes left main loudspeaker 30 and right main loudspeaker 32. A listener 34 is located off-centre. Each loudspeaker 30,32 includes a plurality of respective main drivers 36a,36b (comprising mid-range and high frequency loudspeaker drive units for direct sound reproduction) located on the inward face (i.e. towards the opposite loudspeaker 32,30 respectively) of each loudspeaker 30,32, a plurality of respective ambience drivers 38a,38b located on the forward face (i.e. generally towards th listener 34) of each loudspeaker 30,32, and a respective high frequency difference signal drivers 40a,40b located on the outward face (i.e. away from the opposite loudspeaker 32,30 respectively) of each loudspeaker 30,32.

In order to minimise the adverse effects of unwanted room reflections, all the main drivers 36a,36b of loudspeakers 30,32 respectively are highly directional (i.e. have very narrow sound dispersion), are positioned on wide loudspeaker baffles directly facing each other, and are collectively configured as a line source of sound energy. The high frequency difference signal drivers 40a,40b comprise either a dome tweeter or a set of ‘line source’ tweeters on the outside baffle of each loudspeaker 30,32, and are fed with high frequency (>700 Hz) difference signals (i.e. right minus left on the left-hand side, and left minus right on the right-hand side).

The front-facing ambience drivers are fed with low level, low frequency (<700 Hz), zero delay difference signals (i.e. left minus right on the left-hand side, and right minus left on the right-hand side) which are representative of recorded early reflections (ambience) from the original performance and venue

The listener 34 can be located anywhere in the ‘near field’ in order to minimise adverse room reflection effects and hence maximise the precision of direct sound localisation as well as the efficiency with which the system's multiple sound cues for true spatial surround effects are transmitted to the listener's ears. ‘Near-field’ listening means that the listener 34 should be positioned somewhere between the left and right loudspeakers 30,32 and a line parallel to the left and right loudspeakers 30,32 and such that if the listener 34 were to be at the mid-point of this line on the median plane between the two loudspeakers 30,32, the loudspeakers 30,32 would then subtend an angle of approximately 2×45°=90° at a central listener position.)

The left and right loudspeakers 30,32 are calibrated so that with the calibration microphone located in the median plane of the loudspeakers 30,32 and at a normal near field listening distance from the loudspeakers 30,32 (viz. the main drivers 36a,36b subtend an angle of 90° at the microphone) the resultant overall power response for the entire complement of drivers in the loudspeakers 30,32 is flat, preferably from 15 Hz to 20 kHz.

The system also includes a left and right ‘rear’ loudspeaker 42,44 respectively, positioned laterally with respect to a near-field listener located in the median plane bisecting the main loudspeakers 30,32 and at a distance from the main loudspeakers 30,32 such that the main drivers 36a,36b subtend an angle of 90° at the listener 34 position.

As indicated in FIG. 2, each rear loudspeaker 42,44 includes further, rear ambience drivers (not shown) to emit ambience sound signals 46a,46b (identical to those emitted from ambience drivers 38a,38b) directed straight at the ears of listener 34, as well as reverberation sound signals 48a,48b via ‘dipole’ drivers (not shown). The reverberation sound signals are thus reflected off several of the listening room walls before reaching the listener's ears.

The design features of the sub-system for reproducing the ambience sound are as follows:

Low pass filtered (<700 Hz) left and right ambience signals are first derived as difference signals from the two recorded stereo sound channels and then processed via the particular form of ‘shuffler’ circuit specified in Vanderlyn's GB Patent No. 781,186 (filed 9 Aug. 1955). In effect, this circuit acts to remove interaural cross-talk from the resultant ambience sound signals.

Before being fed to four (i.e. two pair) sets of ambience drivers (see below), the ambience signals from the Vanderlyn shuffler circuit are further processed via a special circuit which superimposes a ⅓ octave bandwidth ‘spike’ signal centred at approximately 500 Hz.

This ensures that all the mutually incoherent ambience sound signals in the reproduction system are perceived by the listener as arriving from the lateral direction. The lateralised ambience signals arriving at each of the listener's ears are summed naturally by the listener's hearing mechanism. The two resultant summed ear input signals for ambience are spatially incoherent but temporally coherent with respect to each other. (As discussed further below, these overall partially incoherent signals play a role in broadening the perceived image of the direct sound, just as the ambience sound signals (due to early lateral reflections) in a concert hall broaden the image of the direct sound. If the listener desires any image broadening beyond that of the direct sound soundstage, the level of the ambience signals may be adjusted by the listener so that it exceeds −20 dB relative to the level of the direct sound. However, owing to the temporal coherence between ambience and direct sound, doing so will detract from the localisational accuracy of the direct sound images.)

The front pair of ambience drivers 38a,38b (i.e. those on the front, narrow baffles of the main loudspeakers 30,32) emit the resultant lateralised ambience sound signals at a sound pressure level of approximately 20 dB below the level of the direct sound.

The rear pair of ambience drivers (i.e. those of rear loudspeakers 42,44, positioned laterally to the listener 34) also emit ambience sound signals at a sound pressure level of approximately 20 dB below the level of direct sound.

All four of these ambience sound signals have zero imposed time delay relative to the direct sound signals. The main purpose of the zero-delay ambience sound signal sub-system is so that the ambience signals reach the ears of listener 34 well before any listening room reflections, so that the so-called Haas or Precedence Effect will ensure that the any room reflections present are effectively suppressed by the listener's hearing system. (The listener will ‘localise’ the earlier-arriving lateral ambience sound signals in preference to any listening room sound reflections.)

The design features of the reverberation sound reproduction sub-system are as follows:

As for ambience signals, the left and right reverberation signals are first derived as ‘difference’ signals from the two recorded stereo sound channels and then processed via the same particular form of ‘shuffler’ circuit specified in Vanderlyn's British Patent.

These left and right raw reverberation signals are then delayed by approximately 20 ms (left) and 40 ms (right)—or vice versa—relative to the direct sound signals so that the reverberation signals are temporally incoherent with respect to the respective direct sound signals, as well as being temporally incoherent with respect to each other.

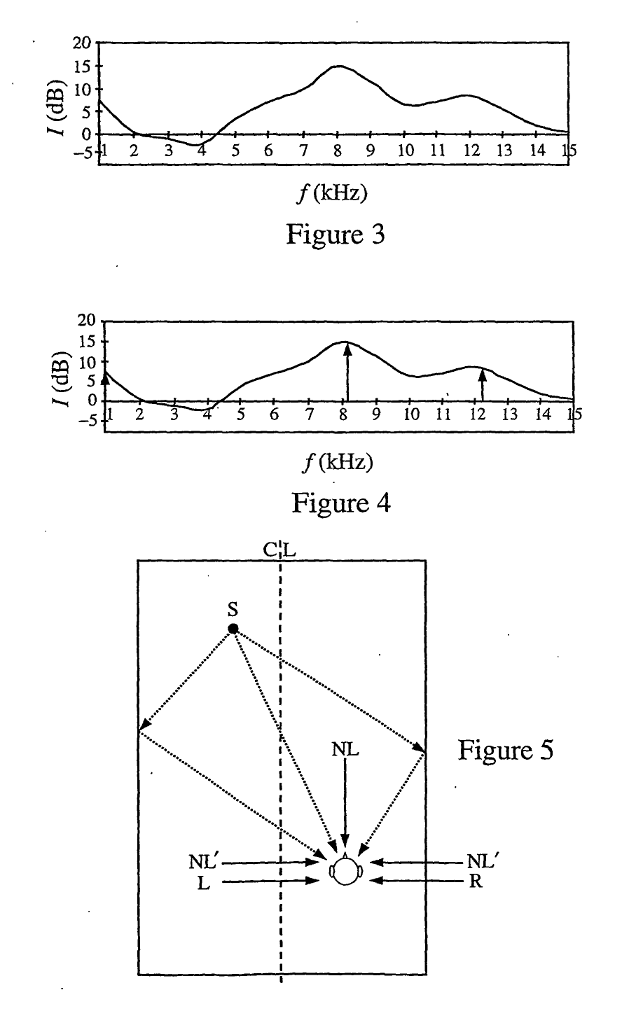

Before being fed to the rear set of reverberation (dipole) loudspeaker drivers of the rear loudspeakers 42,44, the delayed reverberation signals are further processed via a circuit which superimposes a differential (lateral sound incidence relative to frontal sound incidence) Head Related Transfer Function (HRTF). The differential HRTF used for this purpose is presented in FIG. 3, which may be approximated by three or more ‘spike’ signals, at least including those at 1 kHz, 8 kHz and 12 kHz, as shown in FIG. 4. Both figures are plotted as relative sound intensity I (dB) v. frequency f (kHz). FIG. 3 shows the inner ear HRTF Correction for azimuth angle=90° from the front (i.e. to the left or right of the listener 34), while FIG. 4 shows the corresponding ‘spike’ approximation to this inner ear HRTF Correction (again, for azimuth angle=90° from the front (i.e. to the left or right of the listener 34). The exaggerated ‘spikes’ approximation of FIG. 4 is used rather than the continuous frequency spectrum of FIG. 3 so that no unnecessary spectral content is added to the reverberation signals and that all listeners will recognise these exaggerated sound cues for lateral sound incidence.

The reverberation sound signals in the reproduction system are thus perceived by the listener as arriving from the lateral direction. The ear input signals for reverberation should be totally incoherent with respect to each other for maximum spatial impression. Therefore, instead of superimposing an identical set of ‘spikes’ on to the left and right reverberation signals, some of the ‘spikes’ are applied to the left reverberation signal and the remainder to the right reverberation signal. The ear-brain mechanism integrates the two and naturally concludes that these sounds must be arriving from the lateral directions. The lateralised reverberation signals now arriving at each of the listener's ears are temporally incoherent with respect to the direct sound and also spatially incoherent with respect to each other. Since the reverberation signals have an initial imposed delay of 20 to 40 ms plus the additional delay and sound diffusion effect caused by the dipole room reflections, the net approximately 40 to 60 ms time delay relative to direct sound is sufficient to trigger a fuller sense of envelopment of sound for the listener 34, yet with little if any sense of the reverberant sound being adversely echoic.

The rear pair of reverberation drivers emit reverberation sound signals at a sound pressure level of approximately 16 dB below the level of direct sound.

The reverberation sound signal sub-system is provided principally so that these signals reach the listener's ears in a lateralised form, such that the ear input signals are incoherent with respect to each other—so that the maximum degree of original recorded spatial impression is created independent of the domestic listening room acoustics (the latter being, in effect, suppressed by the ambience sound signal sub-system).

The preferred sound pressure levels of both ambience and reverberation signals are low relative to that of direct sound, so that these signals are almost inaudible if reproduced with direct sound switched off. (As indicated above, the ambience signals are typically set at 20 dB below direct sound, and the reverberation signals are typically set at 16 dB below direct sound.)

Optionally, a pair of subwoofer bass drive units (for left and right sound sources) may augment the hardware system (not shown); these subwoofer base units have the following characteristics according to the invention:

They are designed with existing hardware components for subwoofers, but with signal processing for eliminating bass frequency room modes by generating complex comb-filtering of similar-phase signals.

Firstly, an adjustable, low-pass filter is used to isolate the left and right subwoofer bass sound frequencies<50 Hz. For convenience, these are labelled here as the L and R signals. If desired, the listener 34 can adjust the cut-off frequency away from 50 Hz to enable optimum cross-over frequency-matching of the subwoofer bass units with the bass driver units of the front main loudspeakers. Secondly, a composite left and a composite right signal are derived from L and R and ‘mixed’ as follows:

Composite left signal=L+x(L−R)+y(L+R)

Composite right signal=R+x(R−L)+y(R+L)

where 0<x<1.0 and 0<y<1.0, and both x and y are adjustable by the listener via potentiometer controls on the subwoofer bass control unit.

Each of the composite left and composite right signals can thus be adjusted so that the resultant signal containing slightly out-of-phase components is heavily comb-filtered and therefore has a relatively uniform amplitude across the full subwoofer bass frequency spectrum from approximately 0 Hz to 50 Hz (though this latter, cutoff frequency may be adjusted).

In the preferred embodiment, the difference signal components of the composite left and right signals (i.e. x(L−R) and x(R−L) respectively) may also be delayed differentially relative to the other two signal components in order to introduce a degree of temporal incoherence between the composite left and right signals which, in turn, assists in creating an overall sensation of more spatial subwoofer bass. Since the ear-brain hearing mechanism is some 23 dB more sensitive to incoherent ear-input signals compared to coherent ear-input signals, much lower amplifier power is needed to drive the bass loudspeakers to perceived realistic sound levels.

Finally, the relative amplitudes of the various signal components are altered so that the difference signal components are received binaurally by the respective two ears of the listener.

The main loudspeakers 30,32 are also provided with bass drive units (not shown). It is not critical whether the bass drive units for direct sound reproduction of very low recorded frequencies (<<700 Hz) are positioned on either the inward-facing loudspeaker baffles or on the front-facing loudspeaker baffles, or on both. However, it should be noted that if any bass drive units are placed on the inward-facing, wide loudspeaker baffles, they should preferably also be positioned to comply with the ‘line source’ requirement for main drivers 36a,36b producing direct sound from each main loudspeaker 30,32 respectively. It is preferred that any bass drive units placed on the front-facing loudspeaker baffles should be positioned well way from (and preferably well below) the front-facing ambience drivers 38a,38b on this same baffle.

### LOUDSPEAKER SIGNALS

What follows is a summary of all the direct sound signal levels and primary reflected (room mode) sound signal levels reaching each ear, in terms similar to those used above to describe the signals of a prior art system (with reference to FIG. 1).

FIG. 2 shows ten signals 51-60 impinging on the listener 34 located off-centre with respect to two main loudspeakers 30,32 according to the system of this preferred embodiment of the invention. All ten signals are received, at least to some extent, by both ears of the listener 34. The significant additional impact of the lateralised, low level ambience 46a,46b and reverberation 48a,48b signals emanating from the rear loudspeakers 42,44 will be discussed separately below.

Emanating from the ambience drivers 38a,38b on the front baffles of the main loudspeakers 30,32 are low level, low frequency difference or ‘ambience’ signals. These ambience signals are approximately 20 dB lower in sound pressure level than the main stereo, full bandwidth signals which emanate from the main drivers 36a,36b on the inside, wide baffles of the loudspeakers 30,32. Emanating from the dome tweeters (or tweeter line sources) 40a,40b on the outside, wide baffles of the loudspeakers 30,32 are high frequency difference signals as shown in FIG. 2. The ambience signals and the dome tweeter (or tweeter line source) signals are produced by a signal decoder of the system and are then fed to the respective drivers of the main loudspeakers.

According to this embodiment, the ‘line source’ main drivers 36a,36b, which provide the stereo-derived main signals, are (with the exception of any low frequency (<<700 Hz) bass drive units) highly directional. Thus, if listener 34 is located ‘off-axis’ with respect to either loudspeaker 30,32 (as shown in FIG. 2), the frequency response perceived by the listener 34 will be deficient in high frequency content emanating from the nearer loudspeaker (viz. the right loudspeaker 32 for the case shown in FIG. 2).

The following analysis identifies the net signal levels reaching each ear at low frequencies (<700 Hz) and at high frequencies (>700 Hz).

The frequency of 700 Hz is an important one for sound imaging, i.e. localisation of sounds in space. Below about 700 Hz, the ear-brain mechanism locates a sound source on the basis of the ‘interaural time of arrival difference’ (ITD) between the signals which reach the listener's two ears. On the other hand, above about 700 Hz, the ear-brain mechanism locates a sound source on the basis of the ‘intensity difference’ between the signals reaching the listener's two ears. It should also be noted here that for complex music and film motifs, the sound pressure levels of the high frequency signals are derived more from the sound pressure envelope of the composite high frequency content rather than from the sound pressure levels of the fine granularity of the high frequency signals. Thus, the signal phase reversals indicated in FIG. 2 (cf. FIG. 1) caused by sound signals being reflected off the listening room boundaries apply to the sound pressure levels of the low frequency signals and to the envelope waveform of the high frequency signals.

With reference to the signal numbering scheme shown in FIG. 2:

| Low frequency signals reaching | | High frequency signals | |
|---|---|---|---|
| the left ear | | reaching the left ear | |
| 51 | (R − L)_{low level, refleceed} | 51 | − |
| 52 | − | 52 | (l − r)_{reflected} |
| 53 | (L − R)_{low level} | 53 | − |
| 54 | L_{direct} | 54 | l_{direct} |
| 55 | −L_{direct, reflected} | 55 | −l_{direct, reflected} |
| 56 | −R_{direct, reflected, diffracted} | 56 | − |
| 57 | R_{direct, diffracted} | 57 | − |
| 58 | (R − L)_{low level, diffracted} | 58 | − |
| 59 | − | 59 | (r − l)_{reflected, diffracted} |
| 60 | (L − R)_{low level, reflected, diffracted} | 60 | − |

The listener's left ear perceives the sum of these signals:

$$\begin{matrix}{L}_{direct} - {L}_{direct , reflected} + ( {L}_{low level} - {L}_{low level , reflected} ) - \\ ( {L}_{low level , diffracted} - {L}_{low level , reflected , diffracted} ) + \\ ( {R}_{direct , diffracted} - {R}_{direct , reflected , diffracted} ) + \\ ( {R}_{low level , diffracted} - {R}_{low level , reflected , diffracted} ) - \\ ( {R}_{low level} - {R}_{low level , reflected} ) + \\ {l}_{direct} - {l}_{direct , reflected} + \\ ( {l}_{reflected} - {l}_{reflected , diffracted} ) - \\ ( {r}_{reflected} - {r}_{reflected , diffracted} )\end{matrix}$$

The symbol ‘Δ’ again denotes the intensity loss of any signal as a result of a single wall reflection. This summation can therefore be rewritten as:

$$\begin{matrix}{L}_{direct} + {l}_{direct} - {L}_{direct , reflected} - {l}_{direct , reflected} + \\ ( {l}_{reflected} - {l}_{reflected , diffracted} ) + \\ ( Δ {L}_{low level} - Δ {L}_{low level , diffracted} ) + Δ {R}_{direct , diffracted} + \\ Δ {R}_{low level , diffracted} - Δ {R}_{low level} - \\ ( {r}_{reflected} - {r}_{reflected , diffracted} )\end{matrix}$$

Since each of the two bracketed pairs represents the difference between similar second order terms, each one effectively reduces to zero. The summation therefore be approximated by:

$$\begin{matrix}\begin{matrix}( {L}_{full bandwidth , direct} - {L}_{full bandwidth , direct , reflected} ) + \\ ( {l}_{reflected} - {l}_{reflected , diffracted} ) + Δ {R}_{direct , diffracted} -\end{matrix} \\ ( {r}_{reflected} - {r}_{reflected , diffracted} )\end{matrix}$$

Owing to the Haas or Sound Precedence Effect, the listener perceives the earliest signal (i.e. signal L_{full bandwidth,direct}) as dominant over all other signals in the first two bracketed pairs.

The last bracketed pair represents the resultant high frequency interaural cross-talk from the right channel reaching the left ear. (FIG. 2 shows that these two sub-signals originate from signal no. 52 and signal no. 59.) They cancel each other to some extent, depending on how much head shielding (i.e. nullifying) effect is caused by the diffraction of signal no. 59 in reaching the left ear.

In effect, the listener's left ear-brain mechanism is largely free to focus naturally on the dominating full bandwidth signal from the Left channel only of the sound reproduction system. This approximates the prerequisite condition for binaural hearing, i.e. where the left ear, on playback, receives only those signals originally intended by the recording engineer for the left ear.

It is important to note that interaural cross-talk is not completely eliminated. Some interaural cross-talk is still desirable to enable the ear-brain mechanism to locate phantom stereo images in space on the basis of the ITD between stereo source signals for low frequencies (<700 Hz).

In respect of the right ear, and again by reference to the signal numbering of FIG. 2:

| Low frequency signals reaching | | High frequency signals | |
|---|---|---|---|
| the right ear | | reaching the right ear | |
| 51 | (R − L)_{low level, reflected, diffracted} | 51 | − |
| 52 | − | 52 | (l − r)_{delayed, reflected, diffracted} |
| 53 | (L − R)_{low level, diffracted} | 53 | − |
| 54 | L_{diffracted} | 54 | l_{diffracted} |
| 55 | −L_{reflected, diffracted} | 55 | −l_{reflected, diffracted} |
| 56 | −R_{direct, reflected} | 56 | − |
| 57 | R_{direct} | 57 | − |
| 58 | (R − L)_{low level} | 58 | − |
| 59 | − | 59 | (r − l)_{delayed, reflected} |
| 60 | (L − R)_{low level, reflected} | 60 | − |

The listener's right ear perceives the sum of these signals:

$$\begin{matrix}{R}_{direct} - {R}_{direct , reflected} + ( {R}_{low level} - {R}_{low level , reflected} ) - \\ ( {R}_{low level , diffracted} - {R}_{low level , reflected , diffracted} ) + \\ ( {L}_{diffracted} - {L}_{reflected , diffracted} ) + \\ ( {L}_{low level , diffracted} - {L}_{low level , reflected , diffracted} ) - \\ ( {L}_{low level} - {L}_{low level , reflected} ) + \\ {l}_{diffracted} - {l}_{reflected , diffracted} + \\ ( {r}_{delayed , reflected} - {r}_{delayed , reflected , diffracted} ) - \\ ( {l}_{delayed , reflected} - {l}_{delayed , reflected , diffracted} )\end{matrix}$$

The above summation can then be rewritten as:

$$\begin{matrix}{R}_{direct} + {r}_{delayed , reflected} - {R}_{direct , reflected} - \\ {r}_{delayed , reflected , diffracted} + \\ ( Δ {R}_{low level} - Δ {R}_{low level , diffracted} ) + Δ {L}_{diffracted} + \\ ( Δ {L}_{low level , diffracted} - Δ {L}_{low level} ) + \\ {l}_{diffracted} - {l}_{reflected , diffracted} - {l}_{delayed , reflected} + \\ {l}_{delayed , reflected , diffracted}\end{matrix}$$

Since each of the bracketed expressions effectively cancels, the summation may be approximated by:

$$\begin{matrix}\begin{matrix}( {R}_{full bandwidth} - {R}_{full bandwidth , reflected} ) + Δ {L}_{diffracted} + \\ ( {l}_{diffracted} - {l}_{reflected , diffracted} ) -\end{matrix} \\ ( {l}_{delayed , reflected} - {l}_{delayed , reflected , diffracted} )\end{matrix}$$

The first bracketed pair of high frequency interaural cross-talk signals for the right ear effectively cancel each other because they are both small in amplitude (due to the respective diffraction impacts on signal no. 54 and signal no. 55 in reaching the right ear).

Thus, the right ear perceives a net overall signal represented by the expression:

$$\begin{matrix}( {R}_{full bandwidth} - {R}_{full bandwidth , reflected} ) + Δ {L}_{diffracted} - \\ ( {l}_{reflected} - {l}_{reflected , diffracted} )\end{matrix}$$

As with the left ear, the remaining two high frequency interaural cross-talk signals counteract each other to some extent, depending on how much head shielding (i.e. nullifying) effect is caused by the diffraction of signal no. 52 in reaching the right ear.

In effect, the listener's left ear-brain mechanism is largely free to focus naturally on the dominant full bandwidth signal from the right channel only of the sound reproduction system.

Since the high frequency interaural cross-talk signals are virtually eliminated, the listener 34 is not constrained to sit at the traditional ‘sweet spot’ for stereo imaging. The listener has greater freedom to move within a large area of the room and still perceive accurate sound images which remain fixed relative to the room itself.

The highly directional line sources used for generating direct sound in this embodiment are calibrated to provide automatic compensation in relative sound pressure levels at each ear as the listener moves laterally off the median plane between the two front main loudspeakers. For instance, if the listener 34 moves to the right (as shown in FIG. 2), the sound pressure level of the left line source at the left ear is higher, and the sound pressure level of the nearer (right) line source at the right ear is lower. With proper calibration, the listener therefore perceives the sound image as stable with respect to the median plane between the two loudspeakers 30,32.

Finally, the same virtual elimination of high frequency cross-talk signals also eliminates much of the unwanted comb-filtering effects (especially around 2 kHz) which cause extreme ‘phasiness’ or even complete loss of the central phantom images associated with traditional stereo reproduction systems. Consequently, no extra centre channel should be necessary. This is a marked differentiation with respect to contemporary home theatre sound reproduction systems which generally use a central mono channel loudspeaker to anchor film dialogue firmly to the video screen for all listening positions in the room.

The dome tweeter (or tweeter line source) high frequency signals emanating from the drivers 40a,40b on outside baffles of the two main loudspeakers 30,32 have two key roles in this system: 1) as shown in the summation analysis above, for a listening position well off the median plane between the two loudspeakers, these drivers 40a,40b restore the full bandwidth of the direct sounds coming from the nearer loudspeaker; and 2) they help to widen the ‘soundstage’ for the listener by feeding the listener's ears laterally with reflected high frequency sound cues.

The major difference between the two composite signals derived above for a prior art system (by reference to FIG. 1) and the analogous ones for the present system according to the invention lies in the high frequency interaural cross-talk components. In the prior art system there is clearly full high frequency interaural cross-talk present, whereas in the present system, high frequency interaural cross-talk is largely removed. The above analysis shows that this system has these benefits:

By using the primary domestic room reflections to remove almost all the high frequency interaural cross-talk signals, the listener 34 hears sounds in a much more natural fashion. However, enough interaural cross-talk signals remain to enable accurate imaging for low frequency signals.

By using narrow directivity loudspeaker drive units for reproduction of mid-range to high frequencies, coupled with the use of primary domestic room reflections to eliminate otherwise undesirable primary room reflections resulting from traditional front loudspeaker designs, the listener should perceive the natural spatial character of the original recording venue rather than perceive local room reflections (and hence incongruent spatial character of the local room) overlayed on the direct sound of traditional stereo or contemporary Home Theatre sound reproduction systems.

Owing to the combined impact of the binaural spatial surround effect and the primary reflections from the dome tweeters (or line source tweeters) constituting the drivers 40a,40b located on the outside baffles of the loudspeakers 30,32, the resultant soundstage is not constrained to the space bounded by the two front loudspeakers 30,32 and there is also no need for a mono centre channel loudspeaker to ‘anchor’ central stereo images properly.

According to the system of the preferred embodiment, the rear loudspeakers 42,44 help the main loudspeakers 30,32 to recreate the real sense of spaciousness of the original recorded performance.

### REAR LOUDSPEAKERS

The indirect sound signals fed to the rear loudspeakers 42,44 are specified and explained below.

### BACKGROUND

With reference to concert hall listening conditions, Barron (Journal of Sound and Vibration, 15 (4), 1971) and Barron and Marshall (Journal of Sound and Vibration, 77 (2), 1981) analysed the impact of early lateral sound reflections on what they called ‘spatial impression’, the subjective sensation associated with these early lateral reflections. As a measure of the degree of spatial impression, Barron proposed the ratio of lateral to non-lateral sound energy impinging on the listener. The analysis was limited to the impact of lateral sounds arriving within, say, 0-80 ms of the direct (non-lateral) sound. The delay period of 0-80 ms for early lateral reflections is typical of concert hall acoustics, The impact of later-arriving lateral sound energy was not considered.

### CONCERT HALL LISTENING CONDITIONS

Concert hall listening conditions are depicted schematically in FIG. 5, in which the total early sound energy (from source S) impinging on the listener is divided into three components: NL (the energy of non-lateral early sound), L(eft) and R(ight). NL′ represents the left and right ear input signal as a result of NL.

It is assumed that all early sound energy reaching the listener is included in the three components NL, L and R. Under these natural listening conditions, the following observations can be made:

1. There are many lateral reflection paths to each ear of the listener from each sound source.

2. The signals NL, L and R therefore represent summation signals for all lateral reflection paths and for all sound sources.

3. The listener hears all direct and indirect (reflected) sounds binaurally (i.e. each sound source, whether a direct sound source or a reflected signal ‘source’, transmits only one signal to each of the listener's two ears.

4. There is very little difference between the sound pressure levels associated with NL′ and NL.

5. The signals NL′ and NL are highly coherent with respect to each other.

6. The summation signals NL′ and L arrive at the left ear of the listener with significant time-of-arrival difference, and hence are temporally incoherent with respect to each other.

7. Similarly, the summation signals NL′ and R are temporally incoherent with respect to each other at the right ear.

8. Even if the listener is positioned centrally in the median plane of the concert hall, the summation signals L and R will not be identical (coherent) due to the sound sources of the live performance not being perfectly (or symmetrically) positioned in the median plane.

9. The sound sources must be at ‘realistic’ sound pressure levels, since full spatial impression is perceived by the listener only at realistic levels of direct sound.

If we assume that an average figure for the effective sensitivity of each ear to sound pressure from the opposite side is 6 dB (cf. Barron), then:

$$\frac{{p}_{lr}}{{p}_{r}} = r ( r < 1 ) = \frac{{p}_{rl}}{{p}_{l}}$$

where

pₗᵣ=sound pressure level at the left ear due to a signal at the right ear with sound pressure level pᵣ

pᵣₗ=sound pressure level at the right ear due to a signal at the left ear with sound pressure level pₗ

Hence

20 log₁₀ r=−6 dB

∴ r=antilog(−0.3)=0.5

Following Barron's analysis, if Sₗ and Sᵣ are defined as the logarithmic ratios of the respective left and right lateral energy to total non-lateral energy, then:

$$\begin{matrix}{S}_{l} = 10 {log}_{10} \frac{L ( 1 + {r}^{2} )}{NL} ; \\ {S}_{r} = 10 {log}_{10} \frac{R ( 1 + {r}^{2} )}{NL} \\ ∴ {[ ( 1 + antilog \frac{{S}_{l}}{10} ) ( 1 + antilog \frac{{S}_{r}}{10} ) ]}^{- 1 / 2} \\ = {[ ( \frac{NL + L ( 1 + {r}^{2} )}{NL} ) ( \frac{NL + R ( 1 + {r}^{2} )}{NL} ) ]}^{- 1 / 2} \\ = \frac{NL}{\sqrt{[ NL + L ( 1 + {r}^{2} ) ] [ NL + R ( 1 + {r}^{2} ) ]}}\end{matrix} \qquad Equation 1 )$$

Now let K⁰⁻⁸⁰ be the normalised cross-correlation coefficient (also known as the Inter-Aural Cross-correlation Coefficient or IACC) of the two ear input signals due to the combination of direct sound and early reflected sound (<80 ms) for real sound sources in the concert hall. Then:

$$\begin{matrix}{K}^{0 - 80} = \frac{{\int }_{0}^{80} [ {NL}^{′} + L ( 1 + {r}^{2} ) ] [ {NL}^{′} + R ( 1 + {r}^{2} ) ] ⅆ t}{\sqrt{[ {NL}^{′} + L ( 1 + {r}^{2} ) ] [ {NL}^{′} + R ( 1 + {r}^{2} ) ]}} \\ = \frac{{NL}^{′} + {\int }_{0}^{80} [ {NL}^{′} \cdot L ( 1 + {r}^{2} ) ] ⅆ t + {\int }_{0}^{80} {NL}^{′} \cdot R ( 1 + {r}^{2} ) ⅆ t + {\int }_{0}^{80} L \cdot {R ( 1 + {r}^{2} )}^{2} ⅆ t}{\sqrt{[ {NL}^{′} + L ( 1 + {r}^{2} ) ] [ {NL}^{′} + R ( 1 + {r}^{2} ) ]}}\end{matrix} \qquad Equation 2 )$$

The last three integration terms of the numerator are all approximately zero in a concert hall because the signals NL′, L and R are all mutually incoherent (temporally) with respect to each other. If NL′ and NL are taken to be equal (as has been found), then:

$$\begin{matrix}{K}^{0 - 80} = \frac{NL}{\sqrt{[ NL + L ( 1 + {r}^{2} ) ] [ NL + R ( 1 + {r}^{2} ) ]}} \\ Hence , \\ {K}^{0 - 80} = {[ ( 1 + antilog \frac{{S}_{l}}{10} ) ( 1 + antilog \frac{{S}_{r}}{10} ) ]}^{- 1 / 2}\end{matrix} \qquad Equation 3 )$$

If S denotes the logarithmic ratio of total lateral energy to non-lateral energy, then:

$$S = 10 {log}_{10} ( \frac{L + R}{NL} ) dB$$

At this point, in order to simplify the analysis, the listener is assumed to be near the median plane CL (see FIG. 5) of the concert hall.

$$\begin{matrix}Then : \\ L = R , S = 10 {log}_{10} \frac{2 L}{NL} and antilog \frac{S}{10} = \frac{2 L}{NL} \\ Hence , \\ \begin{matrix}{S}_{l} = {S}_{r} = 10 {log}_{10} \frac{L ( 1 + {r}^{2} )}{NL} = 10 {log}_{10} [ ( \frac{1}{2} ) ( antilog \frac{S}{10} ) ( 1 + {r}^{2} ) ] \\ = 10 {log}_{10} ( 0.5 ) + S + 10 {log}_{10} ( 1 + {r}^{2} ) \\ = S - 3 + 1 ( for r = 0.5 ) \\ = S - 2 dB\end{matrix}\end{matrix} \qquad Equation 4 )$$

Substituting Equation 4 into Equation 3 yields:

$$\begin{matrix}{K}^{0 - 80} = {[ ( 1 + antilog \frac{S - 2}{10} ) ( 1 + antilog \frac{S - 2}{10} ) ]}^{- 1 / 2} = \frac{1}{1 + antilog \frac{S - 2}{10}} \\ ∴ 1 - {K}^{0 - 80} = [ antilog \frac{S - 2}{10} ] / [ 1 + antilog \frac{S - 2}{10} ]\end{matrix} \qquad Equation 5 a )$$

The quantity 1−K⁰⁻⁸⁰ is the degree of incoherence between the two ear-input signals for a listener positioned near the median plane of the concert hall.

It should be noted that if r=0 (i.e. for an ideal head shadow effect), then Equation 4 becomes:

Sₗ=Sᵣ=S−3 dB

and Equation 5a would become the same as that derived by Barron, namely:

$$1 - {K}^{0 - 80} = [ antilog \frac{S - 3}{10} ] / [ 1 + antilog \frac{S - 3}{10} ] \qquad Equation 5 b )$$

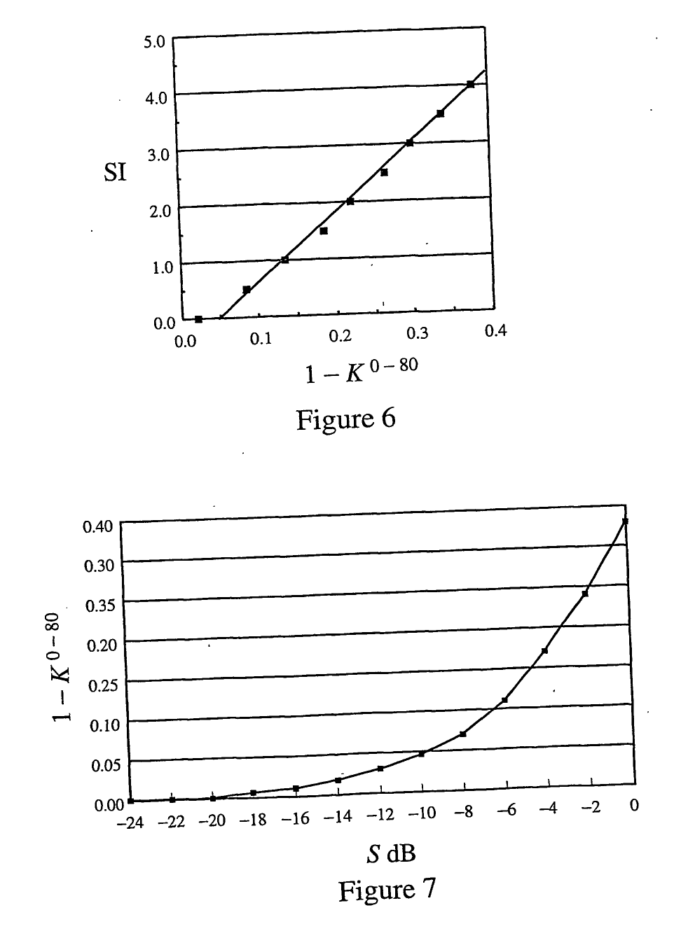

Barron was able to show that on the basis of Equation 5b, the subjective degree of spatial impression (or “spatial broadening” of the sound image) has a strong linear relationship to the degree of incoherence 1−K⁰⁻⁸⁰. Reproduced in FIG. 6 is the relationship between the degree of spatial impression (or SI) and 1−K⁰⁻⁸⁰: the relationship is almost linear, and the higher the value of 1−K⁰⁻⁸⁰, the higher is the subjective degree of spatial impression.

As pointed out by Barron, use of Equation 5a instead of Equation 5b would yield almost the same result. In other words, the ‘head shadowing effect’ has little impact on the perceived degree of spatial broadening in a concert hall.

Under natural listening conditions in a concert hall, the maximum feasible value of S is zero (assuming a frontal performance), corresponding to a situation where the sum of the left lateral and right lateral early sound components equals the non-lateral early sound component.

Substituting S=0 into Equation 5b yields:

$${( 1 - {K}^{0 - 80} )}_{max} = [ antilog \frac{- 3}{10} ] / [ 1 + antilog \frac{- 3}{10} ] = 0.33$$

Barron's full plot of 1−K⁰⁻⁸⁰ for feasible values of S for early lateral reflections is reproduced in FIG. 7 (plotted as 1K⁰⁻⁸⁰ v. Ratio of lateral to non-lateral early sound S (dB)) from the data in Table 3 (for r=0).

All the above analysis is applicable to that component of spatial impression caused by reflections in a concert hall, and characterised mainly by image broadening beyond the actual (direct) sound stage width presented visually to the listener.

It has also been found that full spatial impression incorporating the additional impact of late reflections (reverberation) in a concert hall coincides with much higher values for the degree of incoherence.

To extend the above analysis to include the impact of late reflections it has been surprisingly found that the additional presence of a diffuse, reverberant soundfield of late reflections will create its own auditory event (i.e. as perceived by the listener) which is separate from those created by the direct sound and the early reflected sounds.

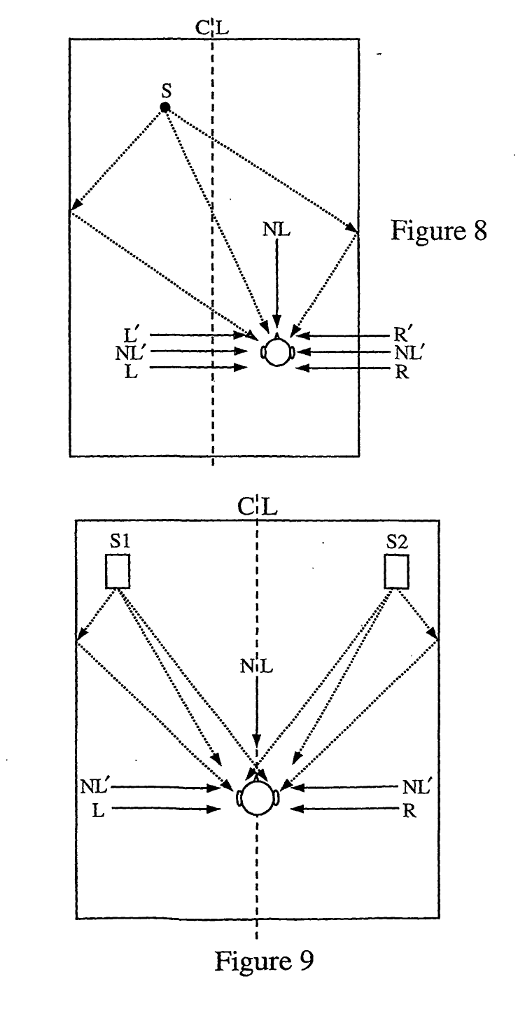

In the presence of an additional reverberant soundfield, the concert hall listening situation becomes that shown schematicallly in FIG. 8 (where S indicates the sound source), which depicts the presence of additional late sound energy components L′ and R′ due to the reverberant soundfield.

Since the reverberation-induced signal L′ and R′ are both totally incoherent with respect to NL (and NL′) and also totally incoherent with respect to each other, each ear is 23 dB more sensitive to the sound pressure level of NL (and NL′).

It follows that:

$$\begin{matrix}\begin{matrix}\begin{matrix}20 {log}_{10} \frac{{p}_{{L}^{′}}}{{p}_{{L}_{effective}^{′}}} = - 23 dB \\ ∴ \frac{{p}_{{L}^{′}}}{{p}_{{L}_{effective}^{′}}} = antilog \frac{- 23}{20} = 0.0708 = a\end{matrix} \\ ∴ \frac{{L}^{′}}{{L}_{effective}^{′}} = {a}^{2}\end{matrix} \\ = \frac{{R}^{′}}{{L}_{effective}^{′}} \begin{matrix}if the listener is in the median \\ plane of the concert hall .\end{matrix}\end{matrix} \qquad Equation 6 )$$

Therefore, under concert hall listening conditions with both early reflections (ambience) and late reflections (reverberation), the effective values of S′ₗ and S′ᵣ are:

$$\begin{matrix}{S}_{l effective}^{′} = 10 {log}_{10} \frac{[ ( L + {L}_{effective}^{′} ) ( 1 + {r}^{2} ) ]}{{NL}^{′}} ; \\ {S}_{r effective}^{′} = 10 {log}_{10} \frac{[ ( R + {R}_{effective}^{′} ) ( 1 + {r}^{2} ) ]}{{NL}^{′}}\end{matrix}$$

If the sound pressure levels of L and NL′ are such that:

$$\frac{{p}_{L}}{{p}_{{NL}^{′}}} = q \\ Then 20 {log}_{10} \frac{{p}_{L}}{{p}_{{NL}^{′}}} = 20 {log}_{10} q and \\ \begin{matrix}\frac{L}{{NL}^{′}} = {q}^{2} \\ = \frac{R}{{NL}^{′}}\end{matrix} \qquad Equation 7 )$$

if the listener is near the median plane of the concert hall.

Similarly, if the sound pressure levels of L′ and NL′ are such that:

$$\frac{{p}_{{L}^{′}}}{{p}_{{NL}^{′}}} = v \\ Then 20 {log}_{10} \frac{{p}_{{L}^{′}}}{{p}_{{NL}^{′}}} = 20 {log}_{10} v and \\ \begin{matrix}\frac{{L}^{′}}{{NL}^{′}} = {v}^{2} \\ = \frac{{R}^{′}}{{NL}^{′}}\end{matrix} \qquad Equation 8 )$$

if the listener is near the median plane of the concert hall.

Substituting Equations 6, 7 and 8 into the respective expressions for S′ₗ effective and S′ᵣ effective yields:

S′_{l effective}=S′_{r effective}=10 log₁₀[(q²+v²/a²)(1+r²)] Equation 9)

$$\begin{matrix} ∴ ( 1 + antilog \frac{{S}_{l effective}^{′}}{10} ) = 1 + ( {q}^{2} + {v}^{2} / {a}^{2} ) ( 1 + {r}^{2} ) \\ ∴ {[ ( 1 + antilog \frac{{S}_{l effective}^{′}}{10} ) ( 1 + antilog \frac{{S}_{r effective}^{′}}{10} ) ]}^{- 1 / 2} = \frac{1}{1 + ( {q}^{2} + {v}^{2} / {a}^{2} ) ( 1 + {r}^{2} )}\end{matrix} \qquad Equation 10 )$$

K⁰⁻²⁰⁰ (the degree of coherence of the composite ear input signals due to early reflections 0-80 ms (ambience) and late reflections 80-200 ms (reverberation)) may then be calculated:

$$\begin{matrix}{K}^{0 - 200} = \frac{{\int }_{0}^{200} [ {NL}^{′} + ( L + {L}_{effective}^{′} ) ( 1 + {r}^{2} ) ] [ {NL}^{′} + ( R + {R}_{effective}^{′} ) ( 1 + {r}^{2} ) ] ⅆ t}{\sqrt{[ {NL}^{′} + ( L + {L}_{effective}^{′} ) ( 1 + {r}^{2} ) ] [ {NL}^{′} + ( R + {R}_{effective}^{′} ) ( 1 + {r}^{2} ) ]}} = \frac{{\int }_{0}^{200} {NL}^{′2} ⅆ t}{\sqrt{{{NL}^{′2} [ 1 + ( {q}^{2} + {v}^{2} / {a}^{2} ) ( 1 + {r}^{2} ) ]}^{2}}} = \frac{1}{1 + ( {q}^{2} + {v}^{2} / {a}^{2} ) ( 1 + {r}^{2} )} & Equation 11 ) \\ ∴ {K}^{0 - 200} = {[ ( 1 + antilog \frac{{S}_{l effective}^{′}}{10} ) ( 1 + antilog \frac{{S}_{r effective}^{′}}{10} ) ]}^{- 1 / 2} & Equation 12 )\end{matrix}$$

From Equations 11 and 12, it follows that:

$$\begin{matrix}1 - {K}^{0 - 200} = \frac{[ ( {q}^{2} + {v}^{2} / {a}^{2} ) ( 1 + {r}^{2} ) ]}{[ 1 + ( {q}^{2} + {v}^{2} / {a}^{2} ) ( 1 + {r}^{2} ) ]} & Equation 13 ) \\ = [ antilog \frac{{S}_{l effective}^{′}}{10} ] / [ 1 + antilog \frac{{S}_{l effective}^{′}}{10} ] & Equation 14 )\end{matrix}$$

If Barron's definition of S is used, that is, with reference to the early lateral energy only, then:

$$\begin{matrix}S = 10 {log}_{10} \frac{2 L}{{NL}^{′}} = 10 {log}_{10} 2 {q}^{2} \\ ∴ antilog \frac{S}{10} = 2 {q}^{2} \\ ∴ {S}_{l effective}^{′} = 10 {log}_{10} \{ [ ( \frac{1}{2} antilog \frac{S}{10} ) + {v}^{2} / {a}^{2} ] ( 1 + {r}^{2} ) \}\end{matrix} \qquad Equation 15 )$$

For varying degrees of S and v, Equation 15 can be used to evaluate the composite degree of incoherence according to Equation 14. The results are presented in Table 1 in which the value of r has been assumed to be 0.5 throughout. The ‘horizontal’ variable in the table is the sound energy of the ambience signal relative to the energy of the non-lateral signal. The ‘vertical’ variable is the sound pressure level of the reverberation signal relative to the level of the non-lateral signal.

TABLE 1
Composite (ambience + reverberation) degree of incoherence,
1-K⁰⁻²⁰⁰ for various combinations of early lateral (ambience)
energy v sound pressure level of lateral reverberation signal.
Composite (ambience + reverberation) Degree of Incoherence 1-K⁰⁻²⁰⁰
(for r = 0.5)
S = Ratio of Total Early Lateral Energy to Non-Lateral Energy (dB)

| | | −24 | −22 | −20 | −18 | −16 | −14 | −12 | −10 | −8 | −6 | −4 | −2 | 0 |
|---|---|---|---|---|---|---|---|---|---|---|---|---|---|---|
| Level of | 0 | 1.00 | 1.00 | 1.00 | 1.00 | 1.00 | 1.00 | 1.00 | 1.00 | 1.00 | 1.00 | 1.00 | 1.00 | 1.00 |
| Lateral Late | −2 | 0.99 | 0.99 | 0.99 | 0.99 | 0.99 | 0.99 | 0.99 | 0.99 | 0.99 | 0.99 | 0.99 | 0.99 | 0.99 |
| Reflection | −4 | 0.99 | 0.99 | 0.99 | 0.99 | 0.99 | 0.99 | 0.99 | 0.99 | 0.99 | 0.99 | 0.99 | 0.99 | 0.99 |
| (Reverberation) | −6 | 0.98 | 0.98 | 0.98 | 0.98 | 0.98 | 0.98 | 0.98 | 0.98 | 0.98 | 0.98 | 0.98 | 0.98 | 0.98 |
| Signal | −8 | 0.98 | 0.98 | 0.98 | 0.98 | 0.98 | 0.98 | 0.98 | 0.98 | 0.98 | 0.98 | 0.98 | 0.98 | 0.98 |
| relative to | −10 | 0.96 | 0.96 | 0.96 | 0.96 | 0.96 | 0.96 | 0.96 | 0.96 | 0.96 | 0.96 | 0.96 | 0.96 | 0.96 |
| non-lateral | −12 | 0.94 | 0.94 | 0.94 | 0.94 | 0.94 | 0.94 | 0.94 | 0.94 | 0.94 | 0.94 | 0.94 | 0.94 | 0.94 |
| signal (dB) | −14 | 0.91 | 0.91 | 0.91 | 0.91 | 0.91 | 0.91 | 0.91 | 0.91 | 0.91 | 0.91 | 0.91 | 0.91 | 0.91 |
| | −16 | 0.86 | 0.86 | 0.86 | 0.86 | 0.86 | 0.86 | 0.86 | 0.86 | 0.86 | 0.87 | 0.87 | 0.87 | 0.87 |
| | −18 | 0.80 | 0.80 | 0.80 | 0.80 | 0.80 | 0.80 | 0.80 | 0.80 | 0.80 | 0.80 | 0.81 | 0.81 | 0.82 |
| | −20 | 0.71 | 0.71 | 0.71 | 0.71 | 0.72 | 0.72 | 0.72 | 0.72 | 0.72 | 0.73 | 0.73 | 0.74 | 0.76 |
| | −22 | 0.61 | 0.61 | 0.61 | 0.61 | 0.61 | 0.62 | 0.62 | 0.62 | 0.63 | 0.63 | 0.65 | 0.66 | 0.69 |
| | −24 | 0.50 | 0.50 | 0.50 | 0.50 | 0.50 | 0.50 | 0.51 | 0.51 | 0.52 | 0.53 | 0.55 | 0.58 | 0.62 |
| | −100 | 0.00 | 0.00 | 0.01 | 0.01 | 0.02 | 0.02 | 0.04 | 0.06 | 0.09 | 0.14 | 0.20 | 0.28 | 0.38 |

Derived from Equation 13, Table 2 presents similar data. This time, the ‘horizontal’ variable in the table is the sound pressure level of the ambience signal relative to the level of the non-lateral signal. In evaluating Equation 13), we make use of the following relationships:

$$\begin{matrix}20 {log}_{10} \frac{{p}_{L}}{{p}_{{NL}^{′}}} = 20 {log}_{10} q = x dB ( abscissa in Table 2 ) \\ ∴ q = antilog \frac{x}{20} \\ 20 {log}_{10} \frac{{p}_{L}}{{p}_{{NL}^{′}}} = 20 {log}_{10} v = y dB ( ordinate in Table 2 ) \\ ∴ v = antilog \frac{y}{20}\end{matrix} \qquad □$$

TABLE 2
Composite (ambience + reverberation) degree of incoherence,
1-K⁰⁻²⁰⁰ for various combinations of early lateral (ambience) sound
pressure level v sound pressure level of lateral reverberation signal.
Composite (ambience + reverberation) Degree of Incoherence 1-K⁰⁻²⁰⁰
(for r = 0.5)
S = Ratio of Total Early Lateral Energy to Non-Lateral Energy (dB)

| | | −24 | −22 | −20 | −18 | −16 | −14 | −12 | −10 | −8 | −6 | −4 | −2 | 0 |
|---|---|---|---|---|---|---|---|---|---|---|---|---|---|---|
| Level of | 0 | 1.00 | 1.00 | 1.00 | 1.00 | 1.00 | 1.00 | 1.00 | 1.00 | 1.00 | 1.00 | 1.00 | 1.00 | 1.00 |
| Lateral Late | −2 | 0.99 | 0.99 | 0.99 | 0.99 | 0.99 | 0.99 | 0.99 | 0.99 | 0.99 | 0.99 | 0.99 | 0.99 | 0.99 |
| Reflection | −4 | 0.99 | 0.99 | 0.99 | 0.99 | 0.99 | 0.99 | 0.99 | 0.99 | 0.99 | 0.99 | 0.99 | 0.99 | 0.99 |
| (Reverberation) | −6 | 0.98 | 0.98 | 0.98 | 0.98 | 0.98 | 0.98 | 0.98 | 0.98 | 0.98 | 0.98 | 0.98 | 0.98 | 0.98 |
| Signal | −8 | 0.98 | 0.98 | 0.98 | 0.98 | 0.98 | 0.98 | 0.98 | 0.98 | 0.98 | 0.98 | 0.98 | 0.98 | 0.98 |
| relative to | −10 | 0.96 | 0.96 | 0.96 | 0.96 | 0.96 | 0.96 | 0.96 | 0.96 | 0.96 | 0.96 | 0.96 | 0.96 | 0.96 |
| non-lateral | −12 | 0.94 | 0.94 | 0.94 | 0.94 | 0.94 | 0.94 | 0.94 | 0.94 | 0.94 | 0.94 | 0.94 | 0.94 | 0.94 |
| signal (dB) | −14 | 0.91 | 0.91 | 0.91 | 0.91 | 0.91 | 0.91 | 0.91 | 0.91 | 0.91 | 0.91 | 0.91 | 0.91 | 0.91 |
| | −16 | 0.86 | 0.86 | 0.86 | 0.86 | 0.86 | 0.86 | 0.86 | 0.86 | 0.86 | 0.87 | 0.87 | 0.87 | 0.87 |
| | −18 | 0.80 | 0.80 | 0.80 | 0.80 | 0.80 | 0.80 | 0.80 | 0.80 | 0.80 | 0.80 | 0.81 | 0.81 | 0.82 |
| | −20 | 0.71 | 0.71 | 0.71 | 0.71 | 0.72 | 0.72 | 0.72 | 0.72 | 0.72 | 0.73 | 0.73 | 0.74 | 0.76 |
| | −22 | 0.61 | 0.61 | 0.61 | 0.61 | 0.61 | 0.62 | 0.62 | 0.62 | 0.63 | 0.63 | 0.65 | 0.66 | 0.69 |
| | −24 | 0.50 | 0.50 | 0.50 | 0.50 | 0.50 | 0.50 | 0.51 | 0.51 | 0.52 | 0.53 | 0.55 | 0.58 | 0.62 |
| | −100 | 0.00 | 0.00 | 0.01 | 0.01 | 0.02 | 0.02 | 0.04 | 0.06 | 0.09 | 0.14 | 0.20 | 0.28 | 0.38 |

Tables 1 and 2 both indicate that in a concert hall, the level of the lateral reverberation signal must be greater than about −16 dB relative to the level of the direct sound signal in order to generate a composite degree of incoherence>0.85 for the listener's ear input signals.

Under these conditions, the listener will perceive the overall sound as “fully enveloping”.

Tables 1 and 2 also show that for any level of the lateral reverberation signal above the −23 dB threshold level, the composite degree of incoherence is largely independent of the level (or energy) of the lateral ambience signal relative to the non-lateral signal level (or energy). However, if the lateral ambience signal level is too low, the listener will not be sufficiently ‘drawn into’ the performance. On the other hand, if the level is too high, the degree of “spatial broadening” reported by Barron will be excessive and will occur at the expense of accurate direct (i.e. non-lateral) sound localisation.

The last rows of Tables 1 and 2 correspond to the situation where there is virtually no reverberation signal at all. The values for the composite degree of incoherence are then almost identical to those predicted by Barron as reproduced here in Table 3:

TABLE 3
Ambience-only degree of incoherence, 1-K⁰⁻²⁰⁰
as a function of S = ratio of total early lateral energy
to non-lateral energy (dB), for r = 0 and for r = 0.5
(after Barron).
Ambience-only Degree of Incoherence 1-K⁰⁻²⁰⁰

| | S (dB) | | | | | | | | | | | | |
|---|---|---|---|---|---|---|---|---|---|---|---|---|---|
| | −24 | −22 | −20 | −18 | −16 | −14 | −12 | −10 | −8 | −6 | −4 | −2 | 0 |
| r = 0.5 | 0.00 | 0.00 | 0.01 | 0.01 | 0.02 | 0.02 | 0.04 | 0.06 | 0.09 | 0.14 | 0.20 | 0.28 | 0.39 |
| r = 0 | 0.00 | 0.00 | 0.00 | 0.01 | 0.01 | 0.02 | 0.03 | 0.05 | 0.07 | 0.11 | 0.17 | 0.24 | 0.33 |

The values for 1−K⁰⁻²⁰⁰ presented in Tables 1 to 3 are consistent with each other. For example, in Table 2, 1−K⁰⁻²⁰⁰=0.91 for x=−12 dB; y=−14 dB.

Further,

$$S = 10 {log}_{10} \frac{2 L}{{NL}^{′}} = 10 {log}_{10} 2 {q}^{2} = 3 + 20 {log}_{10} ( antilog \frac{x}{20} ) = 3 + x - 9 dB$$

Therefore from Table 1, 1−K⁰⁻²⁰⁰=0.91 for S=−9 dB; y=−14 dB.

Traditional Stereo Sound Reproduction Listening Conditions

FIG. 9 depicts the situation in which the live concert hall performance is recorded for subsequent reproduction in a typically small listening room via traditional stereo technology. The listener is assumed to be positioned in the ‘sweet spot’, that is, in the median plane between the two stereo loudspeakers (S1 and S2). The total early sound energy impinging on the listener is again divided into three components NL, L and R. NL′ represents the left and right ear input signal as a result of NL.

The following observations can be made:

1. Compared with a concert hall, there are relatively few lateral reflection paths to each ear of the listener via the walls of the local listening room, and as a result, the ratio of L (and R) to NL′ will be lower. This lowers the degree of spatial broadening of the sound images due to early lateral (room) reflections.

2. What limited sense of spatial broadening remains as a result of listening room reflections has little to do with the spatial impression caused by early reflections within the original recording venue. The resultant sensation is largely artificial and confusing to the ear-brain mechanism which naturally ‘expects’ the direct sound of a concert to be accompanied by the spatial impression of a concert hall, not that of a small listening room.

3. The signals L, R and NL are all highly coherent with respect to each other, and therefore the last three integration terms in the numerator of Equation 10 (and of Equation 2) have finite positive values. These terms increase the value of the composite (i.e. due to early and late reflections) degree of coherence, and therefore decrease the value of the degree of incoherence relative to that of the concert hall listening situation. In turn, this effectively lowers the overall degree of spatial impression perceived by the stereo listener.

4. The presence of interaural cross-talk in the primary (direct) sound signals transmitted from the loudspeakers to the listener's two ears increases the overall composite degree of coherence between the summed ear input signals. This too lowers the overall perceived degree of incoherence of the two ear input signals and hence the overall perceived degree of spatial impression.

As a result of the above cumulative effects, stereo sound reproduction is spatially impoverished.

Contemporary Home Theatre Sound Reproduction Listening Conditions

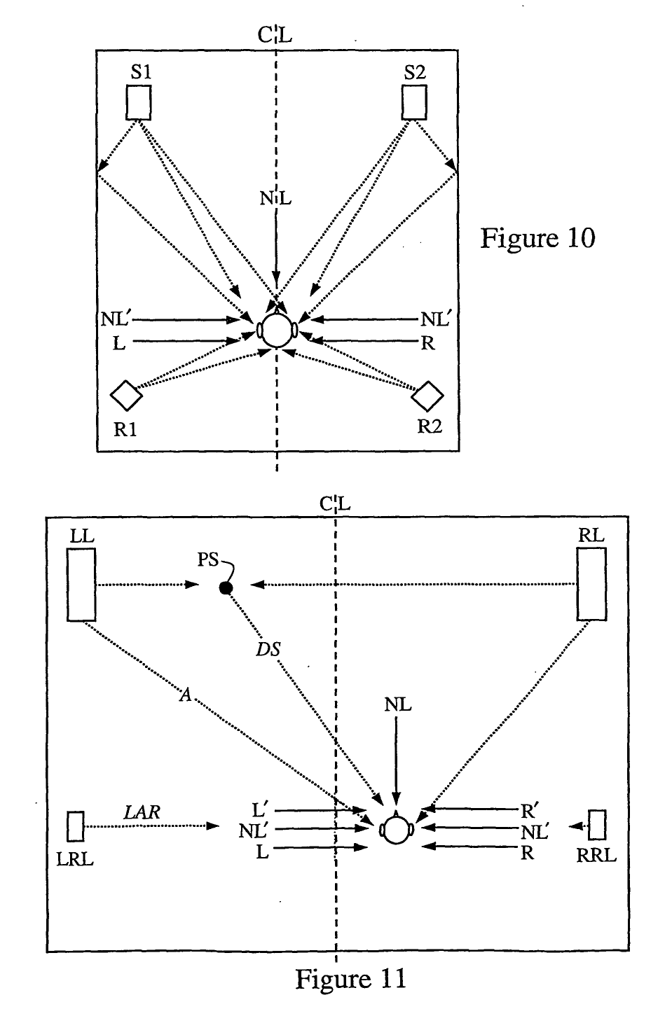

FIG. 10 depicts the situation in which the live concert hall performance is recorded (for subsequent reproduction in a typically small listening room via contemporary home theatre technology). This situation is closely related to that of traditional stereo because the primary (direct) sound signals as well as the surround sound signals all remain stereo based. Again, the listener is assumed to be ideally positioned in the median plane between the loudspeakers to optimise sound localisation accuracy, and the total early sound energy impinging on the listener is divided into three components NL, L and R; NL′ represents the left and right ear input signal as a result of NL.

Again, several observations can be made:

1. As with traditional stereo, there are few lateral listening-room reflection paths to each ear of the listener, and hence the ratio of L (and R) to NL′ will be lower than for natural listening in a concert hall.

2. The signals L and R are normally delayed relative to the non-lateral signals, and so the signals L and R will be temporally incoherent with respect to the NL and NL′ signals. However, signals L and R remain largely coherent with respect to each other. Therefore, only the last of the three integration terms in the numerator of Equation 10 (and of Equation 2) has a finite positive value. This term increases the value of the composite degree of coherence and therefore decreases the value of the degree of incoherence relative to that of the concert hall listening situation. In turn, this lowers the overall degree of spatial impression below that of the live performance (though not to the “spatially impoverished” extent of traditional stereo).

3. Any attempt to increase the spatial impression by increasing the value of S by, in turn, increasing the volume of the ‘surround sound’ signals is doomed to failure. Since the signals L and R remain largely coherent with respect to each other, Damaske (Acustica 19, 1967/68) has shown conclusively that they will always yield a high degree of interaural coherence (approximately 0.95). Increasing the volume will thus have no effect in raising the degree of incoherence to anywhere near the minimum level of 0.85 required for a true sense of “sound envelopment”.

4. There is no mechanism to separately feed highly incoherent reverberation signals (derived from the recording) to the listener's two ears.

Thus, the overall composite degree of incoherence remains below 0.56 (cf. Table 2). Even then, the sound pressure levels of the signals from the ‘surround sound’ loudspeakers would be unnaturally loud to the listener—approaching those of the direct sound. This may be acceptable for intermittent and dramatic cinema sound effects, but it is generally unacceptable for the reproduction of true ambience or reverberation signals of music performances.

As a result of the above cumulative effects, it has been found that contemporary home theatre will generally not provide a realistic spatial impression of live performances.

Binaural Spatial Surround Sound Reproduction Listening Conditions

FIG. 11 depicts the situation in which the binaural system, described above, according to the present invention. The total early sound energy impinging on the listener is divided into three components NL, L and R; NL′ represents the left and right ear input signal as a result of NL. In FIG. 11, LL indicates the left loudspeaker, RL the right loudspeaker, LRL the left rear loudspeaker, RRL the right rear loudspeaker, PS the phantom source, DS direct sound, A ambience, and LAR lateralised ambience plus reverberation.

A comparison of FIGS. 11 and 6 indicates that this listening situation is analogous to that of a live concert hall listening situation.

Under these conditions, Equations 13 and 14 apply. Thus, the values of 1−K⁰⁻²⁰⁰ presented in Tables 1 and 2 also apply to a binaural spatial surround sound reproduction system. A binaural spatial surround system setup in a typically small listening room can readily achieve 1−K⁰⁻²⁰⁰>0.85, so the resultant sound is perceived by the listener as having all the spatial attributes of the original performance. As distinct from traditional stereo or contemporary home theatre, the local listening room generally plays little part in the listening experience. Even the problems of “vaporous imaging” of central images (caused by listening room reflections and comb-filtering due to the presence of interaural cross-talk signals) are suppressed or overcome. The listener can sit or move within the room in front of the two main loudspeakers and still experience a full and stable sound stage, that is, one that does not appear to move with respect to the two main loudspeakers. Furthermore, the incorporation of proper ambience and reverberation signals into the overall sonic experience restores the full frequency spectrum of the overall sonic experience. This also results in greater perceived dynamic range.

Finally, use of the subwoofer bass system specified in this patent yields realistically ‘tight’ bass extension and an additional sense of spatial impression at much lower amplifier power levels than for contemporary subwoofer designs.

It should be noted that, just as with a concert hall performance, the primary sound sources of the system (i.e. the main loudspeaker pair) should be played at realistic sound pressure levels, because only then will the full spatial impression of the original performance be evident.

Software System for Reproduction of Binaural Spatial Surround Sound

According to the present invention it is therefore possible to make the improved reproduction of existing recordings, but also to make original recordings of live performances in accordance with the invention, and to remaster existing recordings.

Since the new recordings or remastered recordings involve effective removal of interaural cross-talk on replay, and also restore both ambience and reverberation of the original performance on replay, listening to the resultant recordings is far more realistic than listening to the original two-channel stereo master tapes.

Accordingly, in a preferred embodiment, the invention provides a system for producing high fidelity recordings (or of remastering existing recordings) as follows.

This system uses Blumlein (coincident) microphone recording techniques rather than spaced-array microphone techniques in order to record and eventually reproduce natural ambience and natural reverberation of the original performance. Spaced-array microphone techniques produce only an artificial version of spatial impression of the original performance.

The mastering process begins with the original (unaltered) two channels (left and right) extracted from the microphones. In the case of remastering an existing recording, the raw material is the two original stereo channels.

The ‘difference’ (i.e. R−L and L−R) ambience and reverberation signal components are both extracted from the two channels and treated separately before being re-mixed with the two main channels of direct sound. In the case of reverberation, different (for each ear) differential HRTFs must be applied to the extracted and delayed (by approximately 20 to 40 ms) left and right reverberation signals before being remixed.

A minimum of sound equalisation (preferably zero) is applied to avoid artificially contaminating the overall resultant recording.

This system can also be applied to sound signals transmitted for radio or television.

Modifications within the spirit and scope of the invention may readily be affected by persons skilled in the art. It is to be understood, therefore, that this invention is not limited to the particular embodiments described by way of example hereinabove.

1. An apparatus for the reproduction of sound in a listening environment, said sound including a left channel and a right channel and each of said channels including a high frequency component and a low frequency component, comprising:
means for comparing said left and right channels and forming left and right comparison signals therefrom;
at least one left loudspeaker means for reproducing said left channel and said left comparison signal; and
at least one right loudspeaker means for reproducing said right channel and said right comparison signal;
wherein said apparatus is operable to reproduce said first and second comparison signals by means of said loudspeaker means, and said left and right comparison signals are, or said apparatus is operable to reproduce said left and right comparison signals to be, substantially incoherent with respect to each other and at a low level relative to said left and right channels, to produce a binaural effect for a listener in said listening environment.

2. An apparatus as claimed in claim 1, wherein said means for comparing said left and right channels and forming left and right comparison signals therefrom is operable to form a plurality of pairs of left and right comparison signals therefrom.

3. An apparatus as claimed in either claim 1 or 2, wherein each of said low frequency components comprises frequencies below approximately 700 Hz and each of said high frequency components comprises frequencies above approximately 700 Hz.

4. An apparatus as claimed in any one of the preceding claims, wherein said means for forming a comparison between said left and right channels and forming left and right comparison signals therefrom comprises:
means for deriving said left comparison signal in the form of a left ambience signal comprising a low frequency difference signal derived from said left low frequency component minus said right low frequency component; and
means for deriving said right comparison signal in the form of a right ambience signal comprising a low frequency difference signal derived from said right low frequency component minus said left low frequency component;
wherein said apparatus is operable to reproduce said left and right ambience signals substantially temporally coherently relative to said left and right channels, whereby a listener's awareness of unwanted primary sound reflections in said listening environment is reduced or eliminated.

5. An apparatus as claimed in claim 4, operable to reproduce said left and right ambience signals with substantially zero imposed time delay relative to said left and right channels.

6. An apparatus as claimed in either claim 4 or 5, wherein said means for deriving said left and right ambience signals are operable to process said left and right ambience signals by means of the “shuffler” circuit described in GB Patent No. 781,186 or an equivalent thereof.

7. An apparatus as claimed in any one of claims 4 to 6, wherein said means for deriving said left and right ambience signals are operable to augment said left and right ambience signals with a narrow bandwidth signal centred at approximately 500 Hz, to increase the extent to which a listener will perceive the resultant augmented left and right ambience signals as coming from a lateral direction.

8. An apparatus as claimed in claim 7, wherein said narrow bandwidth signal is a ‘spike’ signal with a width of approximately ⅓ octave.

9. An apparatus as claimed in any one of claims 4 to 8, wherein said means for deriving said left and right ambience signals are operable to adjust said signal in width and/or amplitude.

10. An apparatus as claimed in any one of claims 4 to 9, wherein said low level is as low as possible while providing ambient sound.

11. An apparatus as claimed in any one of claims 4 to 10, wherein said low level is such that said left ambience signal is approximately −20 dB relative to said left channel and said right ambience signal is approximately −20 dB relative to said right channel.

12. An apparatus as claimed in any one of claims 4 to 11, wherein each of said left and right loudspeaker means includes a main audio driver means for each of said respective left and right channels, and at least one ambience driver means for each of said respective left and right ambience signals.

13. An apparatus as claimed in claim 12, wherein said main audio driver means of each of said loudspeaker means includes one or more mid-range to high frequency audio drivers for reproducing mid-range to high frequency components of said respective left and right channels, wherein said one or more mid-range to high frequency audio drivers are highly directional, that is, have a low sound dispersion.

14. An apparatus as claim d in claim 13, wherein said mid-range to high frequency audio drivers of each of said loudspeaker means are arranged to act collectively as a line source of sound energy with respect to a listener.

15. An apparatus as claimed in either claim 13 or 14, wherein each of said loudspeaker means includes a wide baffle, and said respective mid-range to high frequency audio drivers are arranged on said respective wide baffles, wherein said wide baffles are optimally, in use, located opposite and facing each other.

16. An apparatus as claimed in any one of claims 13 to 15, wherein said at least one ambience driver of said left loudspeaker means is located on said left loudspeaker means to direct reproduced sound in a direction substantially perpendicular to that of reproduced sound from said mid-range to high frequency audio drivers of said left loudspeaker means, and said at least one ambience driver of said right loudspeaker means is located on said right loudspeaker means to direct reproduced sound in a direction substantially perpendicular to that of reproduced sound from said mid-range to high frequency audio drivers of said right loudspeaker means.

17. An apparatus as claimed in any one of claims 13 to 16, further including a left ambience loudspeaker means for locating laterally left of a listener and a right ambience loudspeaker means for locating laterally right of said listener, whereby said left ambience loudspeaker means is for reproducing said left ambience signal and said right ambience loudspeaker means is for reproducing said right ambience signal.

18. An apparatus as claimed in any one of the preceding claims, wherein said means for comparing said left and right channels includes:
means for deriving a left high frequency difference signal from said high frequency components; and
means for deriving a right high frequency difference signal from said high frequency components;
wherein said apparatus is configured to reproduce said left and right high frequency difference signals substantially coherently relative to said left and right channels and to set or to adjust the amplitudes of said left and right high frequency difference signals relative to said left and right channels and left and right ambience signals to maximize the binaural effect for a listener in said listening environment.

19. An apparatus as claimed in claim 18, operable to reproduce said left and right high frequency difference signals with substantially zero imposed time delay relative to said left and right channels.

20. An apparatus as claimed in either claim 18 or 19, wherein:
said left high frequency difference signal is derived from said right high frequency component minus said left high frequency component; and
said right high frequency difference signal is derived from said left high frequency component minus said right high frequency component.

21. An apparatus as claimed in any one of the preceding claims, wherein said left loudspeaker means includes one or more left tweeter drivers to act collectively as a line source for reproducing said left high frequency difference signal, and said right loudspeaker means includes one or more right tweeter drivers to act collectively as a line source for reproducing said right high frequency difference signal, wherein said left tweeter drivers are located on said left loudspeaker means to direct reproduced sound in a direction substantially opposite to that of reproduced sound from said mid-range and higher frequency audio drivers of said left loudspeaker means, and said right tweeter drivers are located on said right loudspeaker means to direct reproduced sound in a direction substantially opposite to that of reproduced sound from said mid-range and higher frequency audio drivers of said right loudspeaker means.

22. An apparatus as claimed in claim 21, wherein each of said left and right loudspeaker means includes an external tweeter baffle on which are located said respective left and right tweeter drivers.

23. An apparatus as claimed in any one of the preceding claims, including means for deriving left and right reverberation signals from the difference between said left channel and said right channel, wherein said left and right reverberation signals are substantially temporally incoherent with respect to said left and right channels, are substantially incoherent with respect to each other and are, or said apparatus is operable for reproducing said left and right reverberation signals, at a low level relative to said left and right channels so as to provide reverberant sound.

24. An apparatus as claimed in claim 23, wherein said means for deriving left and right reverberation signals is operable to derive said left reverberation signal from said left channel minus said right channel, and said right reverberation signal from said right channel minus said left channel.

25. An apparatus as claimed in either claim 23 or 24, wherein said low level is such that said left reverberation signal is approximately −16 dB relative to said left channel and said right reverberation signal is approximately −16 dB relative to said right channel.

26. An apparatus as claimed in either claim 23 or 25, wherein said left and right reverberation signals are delayed relative to said respective left and right channels.

27. An apparatus as claimed in either claim 23 or 25, wherein said left and right reverberation signals are delayed relative to said respective left and right channels by approximately 20 to 40 ms.

28. An apparatus as claimed in either claim 23 or 25, wherein a first of said left and right reverberation signals is delayed relative to said respective left or right channel by approximately 20 ms, and the other of said left and right reverberation signals is delayed relative to the first by a further 20 ms.

29. An apparatus as claimed in either claim 23 or 28, wherein said means for deriving said first and second reverberation signals are operable to said first and second reverberation signals by means of the “shuffler” circuit described in GB Patent No. 781,186 or equivalent.

30. An apparatus as claimed in either claim 23 or 29, wherein said means for deriving said first and second reverberation signals are operable to modify said first and second reverberation signals to simulate the shadowing effect on said first and second reverberation signals of the head of a listener by means of a head related transfer function that simulates said shadowing.

31. An apparatus as claimed in any one of claims 23 to 30, wherein said means for deriving said first and second reverberation signals are operable to modify said first and second reverberation signals by respective first and second different differential head related transfer functions.

32. An apparatus as claimed in claim 31, wherein each of said differential head related transfer functions is in the form of an approximation including a plurality of narrow bandwidth peaks and troughs of different amplitudes, wherein said peaks and troughs differ between differential head related transfer functions.

33. An apparatus as claimed in any one of claims 23 to 32, including a left reverberation loudspeaker means for locating laterally left of a listener and a right reverberation loudspeaker means for locating laterally right of said listener, whereby said left reverberation loudspeaker means is for reproducing said left reverberation signal and said right reverberation loudspeaker means is for reproducing said right reverberation signal.

34. An apparatus as claimed in any one of claims 23 to 33, wherein, when said apparatus includes left and right ambience loudspeaker means, said left ambience loudspeaker means is said left reverberation loudspeaker means, and said right ambience loudspeaker means is said right reverberation loudspeaker means.

35. An apparatus as claimed in any one of the preceding claims, wherein said means for comparing said left and right channels comprises:
means for deriving a left subwoofer signal from a first combination of signals comprising:
a very low frequency component of said left channel,
a difference component comprising said very low frequency component of said left channel minus a very low frequency component of said right channel, and
a summed component comprising said very low frequency component of said left channel plus said very low frequency component of right channel; and
means for deriving a right subwoofer signal from a second combination of signals comprising:
said very low frequency component of said right channel,
a difference component comprising said very low frequency component of said right channel minus said very low frequency component of said left channel, and
a summed component comprising said very low frequency component of said right channel plus said very low frequency component of said left channel,
wherein each of said first and second combinations are delayed relative to said respective left and right channels by between 15 and 1000 ms.

36. An apparatus as claimed in claim 35, wherein each of said first and second combinations are delayed relative to said respective left and right channels by between 20 and 300 ms.

37. An apparatus as claimed in either claim 35 or 36, wherein said low level is such that said left subwoofer signal is approximately −25 dB relative to said left channel and said right subwoofer signal is approximately −25 dB relative to said right channel.

38. An apparatus as claimed in any one of claims 35 to 37, including combination adjustment means for adjusting said first and second combinations, so that said left and right subwoofer signals are substantially incoherent with respect to each other.

39. An apparatus as claimed in any one of claims 35 to 38, wherein said subwoofer signals include lower and higher frequency components and said lower frequency components are amplified relative to said higher frequency components.

40. An apparatus as claimed in any one of claims 35 to 39, wherein the effective cross-over frequency of said difference components is different from that of said summed components, and said respective difference components include an imposed adjustable time delay relative to said respective summed components.

41. An apparatus as claimed in any one of claims 35 to 40, operable to modify the relative amplitudes of the components constituting said first and second combinations so that said difference components are received binaurally by each respective ear of a listener.

42. An apparatus as claimed in any one of claims 35 to 41, wherein said left and right subwoofer signals have a maximum frequency cutoff of 50 Hz.

43. An apparatus as claimed in claim 42, wherein said apparatus includes cutoff adjustment means for adjusting said cutoff.

44. An apparatus as claimed in any one of the preceding claims, wherein said left and right loudspeaker means are calibrated to produce a flat overall power response from 15 Hz to 20 kHz determined with a calibration microphone located in the median plane with respect to said loudspeaker means, and at a normal near-field listening distance therefrom, so that left and right primary front loudspeaker means subtend an angle of substantially 90° at said calibration microphone.

45. A method of reproducing a sound recording in a listening environment, said sound recording including a left channel and a right channel and each of said channels including a high frequency component and a low frequency component, involving:
comparing said left and right channels and forming left and right comparison signals therefrom;
reproducing said left channel and said left comparison signal by means of at least one left loudspeaker means; and
reproducing said right channel and said right comparison signal by means of at least one right loudspeaker means;
whereby said left and right comparison signals are, or are reproduced as, substantially incoherent relative to each other and at a low level relative to said left and right channels, to produce a binaural effect for a listener in said listening environment.

46. A method as claimed in claim 45, including comparing said left and right channels and forming a plurality of pairs of left and right comparison signals therefrom.

47. A method as claimed in either claim 45 or 46, wherein each of said low frequency components comprises frequencies below approximately 700 Hz and each of said high frequency components comprises frequencies above approximately 700 Hz.

48. A method as claimed in any one of claims 45 to 47, wherein said forming said left and right comparison signals involves:
deriving said left comparison signal in the form of a left ambience signal comprising a low frequency difference signal derived from said left low frequency component minus said right low frequency component; and
deriving said right comparison signal in the form of a right ambience signal comprising a low frequency difference signal derived from said right low frequency component minus said left low frequency component;
wherein said left and right ambience signals are reproduced substantially temporally coherently with said left and right channels, whereby a listener's awareness of unwanted primary sound reflections in said listening environment is reduced or eliminated.

49. A method as claimed in claim 48, wherein said left and right ambience signals have, or are reproduced with, substantially zero imposed time delay with respect to said left and right channels.

50. A method as claimed in either claim 48 or 49, wherein said low level is as low as possible while providing ambient sound.

51. A method as claimed in any one of claims 48 to 50, wherein said low level is such that said left ambience signal is approximately −20 dB relative to said left channel and said right ambience signal is approximately −20 dB relative to said right channel.

52. A method as claimed in any one of claims 48 to 51, including processing said left and right ambience signals by means of the “shuffler” circuit described in GB Patent No. 781,186 or an equivalent thereof.

53. A method as claimed in any one of claims 48 to 52, including augmenting said left and right ambience signals with a narrow bandwidth signal centred at approximately 500 Hz, to increase the extent to which a listener will perceive the resultant augmented left and right ambience signals as coming from a lateral direction.

54. A method as claimed in claim 53, wherein said narrow bandwidth signal is a ‘spike’ signal with a width of approximately ⅓ octave.

55. A method as claimed in claim 54, including adjusting said narrow bandwidth signal in width and/or amplitude to optimize said binaural effect.

56. A method as claimed in any one of claims 48 to 55, including calibrating said left and right loudspeaker means to produce a flat overall power response from 15 Hz to 20 kHz determined with a calibration microphone located in the median plane with respect to said loudspeaker means, and at a normal near-field listening distance therefrom, so that left and right primary front loudspeaker means subtend an angle of substantially 90° at said calibration microphone.

57. A method as claimed in any one of claims 48 to 56, including reproducing mid-range to high frequency components of said left and right channels highly directionally, whereby said mid-range to high frequency components of said left and right channels are reproduced with low sound dispersion.

58. A method as claimed in any one of claims 48 to 57, wherein said mid-range to high frequency components of said left and right channels are reproduced by means of respective main audio driver means comprising respective one or more highly directional mid-range to high frequency audio drivers.

59. A method as claimed in claim 58, including arranging said mid-range to high frequency audio drivers of each of said loudspeaker means to act collectively as respective line sources of sound energy with respect to a listener.

60. A method as claimed in either claim 58 or 59, including arranging each of said respective mid-range to high frequency audio drivers on respective wide baffles on each of said respective loudspeaker means, and locating said wide baffles opposite and facing each other.

61. A method as claimed in any one of claims 58 to 60, including reproducing said left ambience signals in a direction substantially perpendicular to that of reproduced sound from said mid-range to high frequency audio drivers of said left loudspeaker means, and said right ambience signal in a direction substantially perpendicular to that of reproduced sound from said mid-range to high frequency audio drivers of said right loudspeaker means.

62. A method as claimed in any one of claims 48 to 61, including said method further includes reproducing said left ambience signal means laterally left of and generally towards a listener, and said right ambience signal laterally right of and generally towards said listener.

63. A method as claimed in any one of claims 48 to 62, wherein said forming said left and right comparison signals includes:
deriving a left high frequency difference signal from said high frequency components; and
deriving a right high frequency difference signal from said high frequency components;
reproducing said left and right high frequency difference signals substantially coherently relative to said left and right channels, and setting or adjusting the amplitudes of said left and right high frequency difference signals relative to said left and right channels and left and right ambience signals to maximize the binaural effect for a listener in said listening environment.

64. A method as claimed in claim 63, including reproducing said left and right high frequency difference signals with substantially zero imposed time delay relative to said left and right channels.

65. A method as claimed in claim 64, including deriving said left high frequency difference signal from said right high frequency component minus said left high frequency component; and
deriving said right high frequency difference signal from said left high frequency component minus said right high frequency component.

66. A method as claimed in any one of claims 63 to 65, including reproducing said left high frequency difference signal by means of one or more left tweeter drivers arranged to act collectively as a line source, and reproducing said right high frequency difference signal by means of one or more right tweeter drivers arranged to act collectively as a line source.

67. A method as claimed in any one of claims 63 to 66, including reproducing said left high frequency difference signal in a direction substantially opposite to that of said left channel, and reproducing said right high frequency difference signal in a direction substantially opposite to that of said right channel.

68. A method as claimed in any one of claims 45 to 67, including deriving left and right reverberation signals from the difference between said left and right channels, wherein said left and right reverberation signals are, or are reproduced, substantially temporally incoherent with respect to said left and right channels, substantially incoherent with respect to each other and at a low level relative to said left and right channels so as to provide reverberant sound.

69. A method as claimed in claim 68, including deriving said left reverberation signal from said left channel minus said right channel, and said right reverberation signal from said right channel minus said left channel.

70. A method as claimed in either claim 68 or 69, wherein said low level is such that said left reverberation signal is approximately −16 dB relative to said left channel and said right reverberation signal is approximately −16 dB relative to said right channel.

71. A method as claimed in any one of claims 68 to 70, including delaying said left and right reverberation signals relative to said respective left and right channels.

72. A method as claimed in any one of claims 68 to 70, including delaying said left and right reverberation signals relative to said respective left and right channels by approximately 20 to 40 ms.

73. A method as claimed in any one of claims 68 to 70, including delaying a first of said left and right reverberation signals relative to said respective left or right channel by approximately 20 ms, and delaying the other of said left and right reverberation signals relative to the first by a further 20 ms.

74. A method as claimed in any one of claims 68 to 73, including processing said first and second reverberation signals by means of the “shuffler” circuit described in GB Patent No. 781,186 or equivalent.

75. A method as claimed in any one of claims 68 to 74, including modifying said first and second reverberation signals to simulate the shadowing effect on said first and second reverberation signals of the head of a listener by means of a head related transfer function that simulates said shadowing.

76. A method as claimed in claim 75, including modifying said first and second reverberation signals by means of respective first and second different differential head related transfer functions.

77. A method as claimed in claim 76, wherein each of said differential head related transfer functions is in the form of an approximation including a plurality of narrow bandwidth peaks and troughs of different amplitudes, wherein said peaks and troughs differ between differential head related transfer functions.

78. A method as claimed in any one of claims 68 to 77, including reproducing said left and right reverberation signals from left and right of, and generally towards, a listener, respectively.

79. A method as claimed in any one of claims 45 to 78, wherein said forming said left and right comparison signals includes:
deriving a left subwoofer signal from a first combination of signals comprising:
a very low frequency component of said left channel,
a difference component comprising said very low frequency component of said left channel minus a very low frequency component of said right channel, and
a summed component comprising said very low frequency component of said left channel plus said very low frequency component of right channel; and
deriving a right subwoofer signal from a second combination of signals comprising:
said very low frequency component of said right channel,
a difference component comprising said very low frequency component of said right channel minus said very low frequency component of said left channel, and
a summed component comprising said very low frequency component of said right channel plus said very low frequency component of said left channel;
wherein each of said first and second combinations are delayed relative to said respective left and right channels by between 15 and 1000 ms.

80. A method as claimed in claim 79, wherein each of said first and second combinations are delayed relative to said respective left and right channels by between 20 and 300 ms.

81. A method as claimed in either claim 79 or 80, wherein said low level is such that said left subwoofer signal is approximately −25 dB relative to said left channel and said right subwoofer signal is approximately −25 dB relative to said right channel.

82. A method as claimed in any one of claims 79 to 81, including adjusting said first and second combinations, so that said left and right subwoofer signals are substantially incoherent with respect to each other.

83. A method as claimed in any one of claims 79 to 82, wherein said subwoofer signals include lower and higher frequency components, and said method includes amplifying said lower frequency components relative to said higher frequency components.

84. A method as claimed in any one of claims 79 to 83, wherein the effective cross-over frequency of said difference components is different from that of said summed components, and said method includes imposing an adjustable time delay on said respective difference components relative to said respective summed components.

85. A method as claimed in any one of claims 79 to 84, including modifying the relative amplitudes of said components so that said difference components are received binaurally by each respective ear of a listener.

86. A method as claimed in any one of claims 79 to 85, wherein said left and right subwoofer signals have a maximum frequency cutoff of approximately 50 Hz.

87. A method as claimed in claim 86, including adjusting said maximum frequency cutoff.

88. A method of deriving ambience signals from a left audio channel and a right audio channel, involving:
deriving a left ambience signal comprising a low frequency difference signal derived from a left low frequency component of said left channel minus a right low frequency component of said right channel; and
deriving a right ambience signal comprising a low frequency difference signal derived from said right low frequency component minus said left low frequency component.

89. A method as claimed in claim 88, including reproducing said left and right ambience signals substantially temporally coherently with said left and right channels, whereby a listener's awareness of unwanted primary sound reflections is reduced or eliminated.

90. A method of deriving reverberation signals from a left audio channel and a right audio channel, involving:
deriving left and right reverberation signals from the difference between said left and right channels.

91. A method as claimed in claim 90, wherein said left and right reverberation signals are, or are reproduced to be, substantially temporally incoherent with respect to said left and right channels, substantially incoherent with respect to each other and at a low level relative to said left and right channels so as to provide reverberant sound.

92. A method of deriving subwoofer signals from a left audio channel and a right audio channel, involving:
deriving a left subwoofer signal from a first combination of signals comprising:
a very low frequency component of said left channel,
a difference component comprising said very low frequency component of said left channel minus a very low frequency component of said right channel, and
a summed component comprising said very low frequency component of said left channel plus said very low frequency component of right channel; and
deriving a right subwoofer signal from a second combination of signals comprising:
said very low frequency component of said right channel,
a difference component comprising said very low frequency component of said right channel minus said very low frequency component of said left channel, and
a summed component comprising said very low frequency component of said right channel plus said very low frequency component of said left channel;
wherein each of said first and second combinations are delayed relative to said respective left and right channels by between 15 and 1000 ms.

93. A method as claimed in claim 92, wherein each of said first and second combinations are delayed relative to said respective left and right channels by between 20 and 300 ms.

94. A method for remastering existing stereophonic sound recordings having a left audio channel and a right audio channel, involving:
deriving ambience signals as claimed in claim 88 or deriving reverberation signals as claimed in claim 90 or deriving subwoofer signals as claimed in claim 92; and
re-recording each of, or combinations of, said left and right channels and signals derived therefrom.

95. A method of recording binaural sound, including:
extracting initial left and right channels from respective left and right microphones;
processing said left and right channels to form comparison signals; and
recording each of or combinations of said left and right channels and said signals derived therefrom;
wherein forming said comparison signals includes deriving ambience signals as claimed in claim 88 or deriving reverberation signals as claimed in claim 90 or deriving subwoofer signals as claimed in claim 92.

96. A method as claimed as claim 95, wherein said microphones for recording said initial left and right channels are coincident microphones.
